(19) United States
(12) Patent Application Publication
(10) Pub. No.: US 2024/0053447 A1
(43) Pub. Date: Feb. 15, 2024

(54) PHOTOELECTRIC CONVERSION ELEMENT, PHOTODETECTOR, PHOTODETECTION SYSTEM, ELECTRONIC APPARATUS, AND MOBILE BODY

(71) Applicant: SONY SEMICONDUCTOR SOLUTIONS CORPORATION, Kanagawa (JP)

(72) Inventors: Tomohiro OHKUBO, Kanagawa (JP); Hitoshi TSUNO, Kanagawa (JP); Hideaki TOGASHI, Kanagawa (JP); Masayuki KURITA, Kanagawa (JP); Syuto TAMURA, Kanagawa (JP); Tetsuro TAKADA, Kanagawa (JP); Nobuhiro KAWAI, Kanagawa (JP); Tomoki HIRAMATSU, Kanagawa (JP); Masahiro JOEI, Kanagawa (JP); Kenichi MURATA, Kanagawa (JP); Hideki TSUJIAI, Kanagawa (JP)

(21) Appl. No.: 18/267,694

(22) PCT Filed: Dec. 3, 2021
(86) PCT No.: PCT/JP2021/044558

§ 371 Date: Jun. 15, 2023

(30) Foreign Application Priority Data
Dec. 16, 2020 (JP) 2020-208719

(51) Int. Cl. G01S 7/481; G01S 17/931

(52) U.S. Cl. CPC G01S 7/4816; G01S 17/931

(57) ABSTRACT

A highly functional photoelectric conversion element is provided. The photoelectric conversion element includes: a plurality of first photoelectric converters that is periodically arranged in each of a first direction and a second direction orthogonal to each other and each detects light in a first wavelength range and each photoelectrically converts the light; and one second photoelectric converter that is stacked on the first photoelectric converter in a stacking direction orthogonal to both the first direction and the second direction, and detects light in a second wavelength range having passed through the plurality of first photoelectric converters and photoelectrically converts the light, in which n times (n is a natural number) a first arrangement period of the plurality of first photoelectric converters in the first direction is substantially equal to a first dimension of the one second photoelectric converter in the first direction, and n times (n is a natural number) a second arrangement period of the plurality of first photoelectric converters in the second direction is substantially equal to a second dimension of the one second photoelectric converter in the second direction.

### TECHNICAL FIELD

The present disclosure relates to a photodetector, a photodetection system, an electronic apparatus, and a mobile body each including a photoelectric conversion element that performs photoelectric conversion.

### BACKGROUND ART

There has been proposed a solid-state imaging device including a stacked structure of a first photoelectric conversion region that receives mainly visible light and photoelectrically converts the visible light and a second photoelectric conversion region that receives mainly infrared light and photoelectrically converts the infrared light (see PTL 1, for example).

### CITATION LIST

### Patent Literature

PTL 1: Japanese Unexamined Patent Application Publication No. 2017-208496

### SUMMARY OF THE INVENTION

Incidentally, in a solid-state imaging device, functional improvement is desired.

It is therefore desirable to provide a highly functional photoelectric conversion element.

A photoelectric conversion element according to an embodiment of the present disclosure includes: a plurality of first photoelectric converters that is periodically arranged in each of a first direction and a second direction orthogonal to each other and each detects light in a first wavelength range and each photoelectrically converts the light; and one second photoelectric converter that is stacked on the first photoelectric converter in a stacking direction orthogonal to both the first direction and the second direction, and detects light in a second wavelength range having passed through the plurality of first photoelectric converters and photoelectrically converts the light, in which n times (n is a natural number) a first arrangement period of the plurality of first photoelectric converters in the first direction is substantially equal to a first dimension of the one second photoelectric converter in the first direction, and n times (n is a natural number) a second arrangement period of the plurality of first photoelectric converters in the second direction is substantially equal to a second dimension of the one second photoelectric converter in the second direction.

In the photoelectric conversion element according to the embodiment of the present disclosure, the plurality of first photoelectric converters is equally allocated to the one second photoelectric converter. In a case where a plurality of photoelectric conversion elements are used in combination, this makes it easy to reduce variations in photoelectric conversion characteristics among the plurality of photoelectric conversion elements.

### BRIEF DESCRIPTION OF DRAWINGS

FIG. 1 is a schematic configuration diagram illustrating an example of a solid-state imaging device according to a first embodiment of the present disclosure.

FIG. 2 is a vertical cross-sectional view of an example of a schematic configuration of an imaging element applied to a pixel section illustrated in FIG. 1.

FIG. 3 is a schematic view of an example of an arrangement state of a plurality of imaging elements in the pixel section illustrated in FIG. 1.

FIG. 4A is a schematic enlarged cross-sectional view of a through electrode and its surroundings illustrated in FIG. 2.

FIG. 4B is a schematic enlarged plan view of the through electrode and its surroundings illustrated in FIG. 2.

FIG. 5 is a circuit diagram illustrating an example of a readout circuit of an iTOF sensor section illustrated in FIG. 2A.

FIG. 6 is a circuit diagram illustrating an example of a readout circuit of an organic photoelectric converter illustrated in FIG. 2A.

FIG. 7 is a schematic cross-sectional view of an example of a schematic configuration of an imaging element according to a first modification example of the first embodiment applied to the pixel section illustrated in FIG. 1.

FIG. 8 is a horizontal cross-sectional view of an example of a schematic configuration of an imaging element according to a second modification example of the first embodiment.

FIG. 9 is a horizontal cross-sectional view of an example of a schematic configuration of an imaging element according to a third modification example of the first embodiment.

FIG. 10 is a horizontal cross-sectional view of an example of a schematic configuration of an imaging element according to a fourth modification example of the first embodiment.

FIG. 11 is a horizontal cross-sectional view of an example of a schematic configuration of an imaging element according to a fifth modification example of the first embodiment.

FIG. 12 is a horizontal cross-sectional view of an example of a schematic configuration of an imaging element according to a sixth modification example of the first embodiment.

FIG. 13 is a horizontal cross-sectional view of an example of a schematic configuration of an imaging element according to a seventh modification example of the first embodiment.

FIG. 14 is a vertical cross-sectional view of an example of a schematic configuration of an imaging element according to a second embodiment of the present disclosure.

FIG. 15 is a horizontal cross-sectional view of an example of a schematic configuration of the imaging element illustrated in FIG. 14.

FIG. 16 is a horizontal cross-sectional view of an example of a schematic configuration of an imaging element according to a first modification example of the second embodiment.

FIG. 17A is a schematic view of an example of an entire configuration of a photodetection system according to a third embodiment of the present disclosure.

FIG. 17B is a schematic view of an example of a circuit configuration of the photodetection system illustrated in FIG. 17A.

FIG. 18 is a schematic view of an entire configuration example of an electronic apparatus.

FIG. 19 is a block diagram depicting an example of a schematic configuration of an in-vivo information acquisition system.

FIG. 20 is a view depicting an example of a schematic configuration of an endoscopic surgery system.

FIG. 21 is a block diagram depicting an example of a functional configuration of a camera head and a camera control unit (CCU).

FIG. 22 is a block diagram depicting an example of schematic configuration of a vehicle control system.

FIG. 23 is a diagram of assistance in explaining an example of installation positions of an outside-vehicle information detecting section and an imaging section.

### MODES FOR CARRYING OUT THE INVENTION

Some embodiments of the present disclosure are described below in detail with reference to the drawings. It is to be noted that the description is given in the following order.
1. First Embodiment

An example of a solid-state imaging device including a plurality of longitudinal spectral type imaging elements in which a plurality of first photoelectric converters including a phase difference detection pixel and a second photoelectric converter are stacked and the second photoelectric converter has a dimension equal to a natural number times an arrangement period of the plurality of first photoelectric converters
2. Second Embodiment

An example of a solid-state imaging device including a plurality of longitudinal spectral type imaging elements in which the second photoelectric converter also includes a phase difference detection pixel
3. Third Embodiment

An example of a photodetection system including a light-emitting device and a photodetector
4. Application Example to Electronic Apparatus
5. Practical Application Example to In-vivo Information Acquisition System
6. Practical Application Example to Endoscopic Surgery System
7. Practical Application Example to Mobile Body
8. Other Modification Examples

### 1. First Embodiment

### [Configuration of Solid-State Imaging Device 1]

### (Overall Configuration Example)

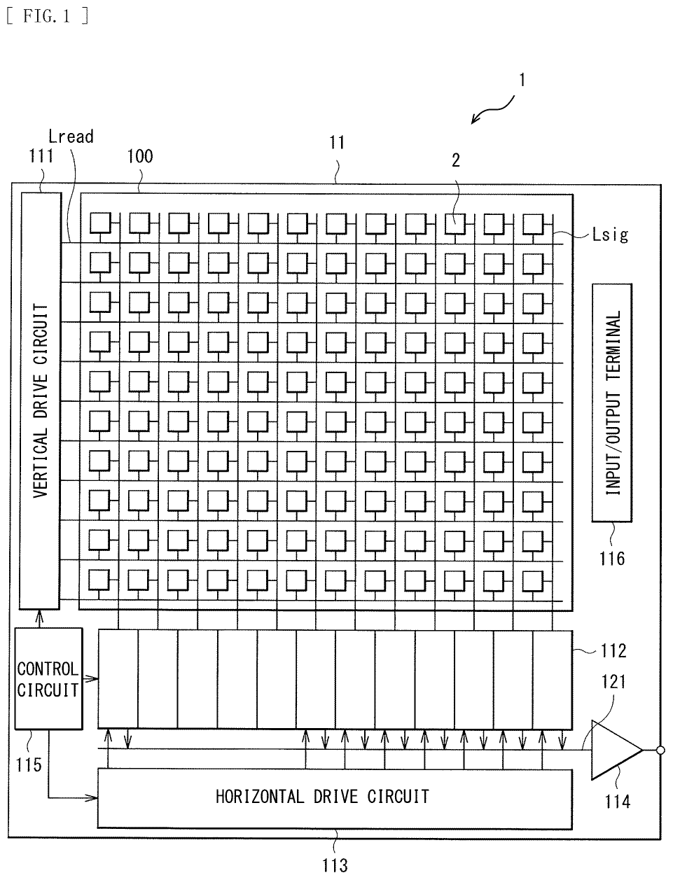

FIG. 1 is an overall configuration example of a solid-state imaging device 1 according to an embodiment of the present disclosure. The solid-state imaging device 1 is, for example, a CMOS (Complementary Metal Oxide Semiconductor) image sensor. For example, the solid-state imaging device 1 captures incident light (image light) from a subject through an optical lens system, converts the incident light of which an image is formed on an imaging plane into an electric signal on a pixel-by-pixel basis, and outputs the electric signal as a pixel signal. The solid-state imaging device 1 includes a pixel section 100 as an imaging region, a vertical drive circuit 111, a column signal processing circuit 112, a horizontal drive circuit 113, an output circuit 114, a control circuit 115, and an input/output terminal 116 on a semiconductor substrate 11, for example. The vertical drive circuit 111, the column signal processing circuit 112, the horizontal drive circuit 113, the output circuit 114, the control circuit 115, and the input/output terminal 116 are disposed in a peripheral region of the pixel section 100, The solid-state imaging device 1 is a specific example corresponding to a “photodetector” of the present disclosure.

The pixel section 100 includes, for example, a plurality of imaging elements 2 two-dimensionally arranged in a matrix. The pixel section 100 has, for example, a plurality of rows each including a plurality of imaging elements 2 disposed side by side in a horizontal direction (a lateral direction on the sheet) and a plurality of columns each including a plurality of imaging elements 2 disposed side by side in a vertical direction (a longitudinal direction on the sheet). In the pixel section 100, for example, one pixel drive line Lread (a row selection line and a reset control line) is wired with each row of the imaging elements 2, and one vertical signal line Lsig is wired with each column of the imaging elements 2. The pixel drive line Lread transmits a drive signal for signal reading from each imaging element 2. A plurality of pixel drive lines Lread each has one end coupled to a corresponding one of a plurality of output terminals, corresponding to respective pixel rows, of the vertical drive circuit 111.

The vertical drive circuit 111 includes a shift register, an address decoder, and the like, and is a pixel driving section that drives the respective imaging elements 2 in the pixel section 100 in row units, for example. A signal outputted from each of the imaging elements 2 in a row selected and scanned by the vertical drive circuit 111 is supplied to the column signal processing circuit 112 through a corresponding one of the vertical signal lines Lsig.

The column signal processing circuit 112 includes an amplifier, a horizontal selection switch, and the like provided for each of the vertical signal lines Lsig.

The horizontal drive circuit 113 includes a shift register, an address decoder, and the like, and drives respective horizontal selection switches of the column signal processing circuits 112 in sequence while scanning the horizontal selection switches. Such selective scanning by the horizontal drive circuit 113 causes the signals of the respective imaging elements 2 transmitted through a plurality of respective vertical signal lines Lsig to be outputted in sequence to a horizontal signal line 121 and be transmitted to outside of the semiconductor substrate 11 through the horizontal signal line 121.

The output circuit 114 performs signal processing on the signals supplied in sequence from the respective column signal processing circuits 112 through the horizontal signal line 121, and outputs the processed signals. The output circuit 114 may perform, for example, only buffering, or may perform black level adjustment, column variation correction, various kinds of digital signal processing, and the like.

Circuit components including the vertical drive circuit 111, the column signal processing circuit 112, the horizontal drive circuit 113, the horizontal signal line 121, and the output circuit 114 may be formed directly on the semiconductor substrate 11, or may be provided in an external control IC. Alternatively, these circuit components may be formed on another substrate coupled by a cable, or the like.

The control circuit 115 receives a clock given from the outside of the semiconductor substrate 11, or data or the like on instructions of operation modes, and also outputs data such as internal information of the imaging element 2 that is an imaging element. The control circuit 115 further includes a timing generator that generates various timing signals, and controls driving of peripheral circuits such as the vertical drive circuit 111, the column signal processing circuit 112, and the horizontal drive circuit 113, on the basis of the various timing signals generated by the timing generator.

The input/output terminal 116 exchanges signals with the outside.

### (Cross-Sectional Configuration Example of Imaging Element 2)

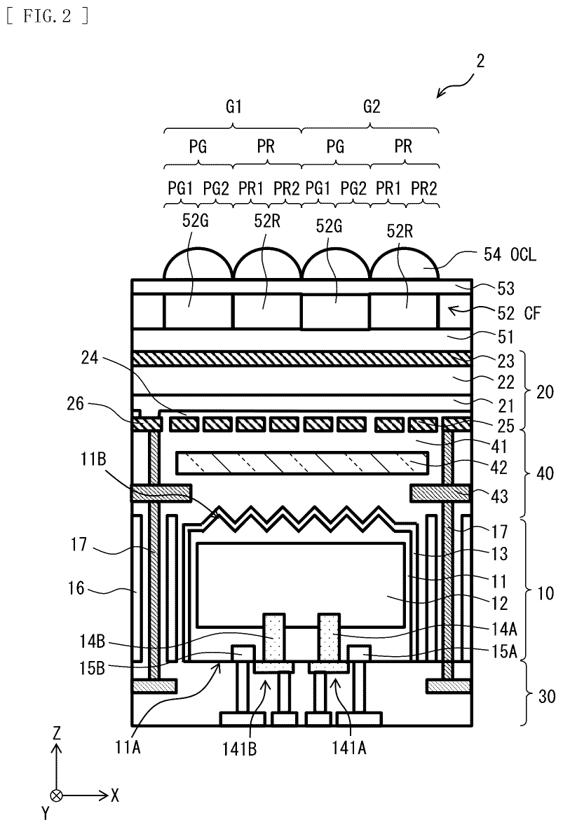

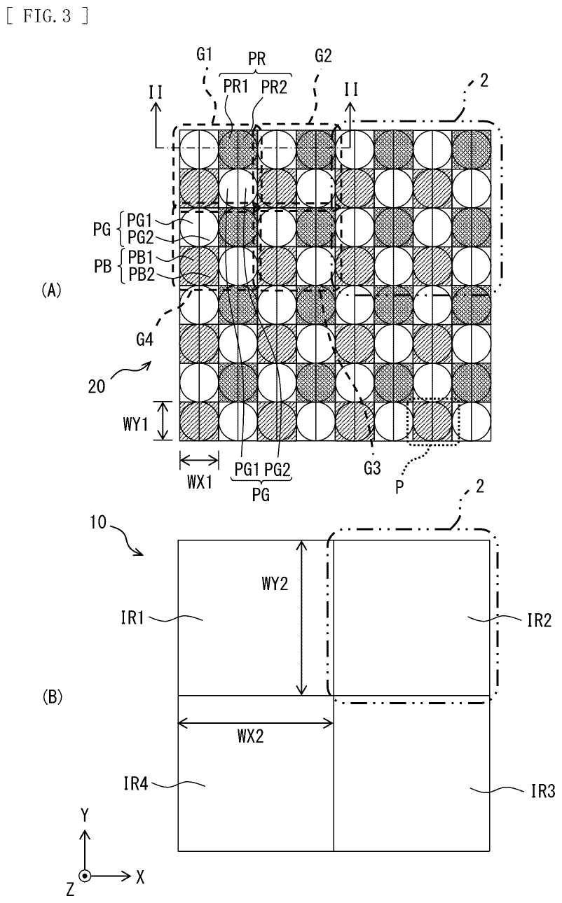

FIG. 2 schematically illustrates an example of a cross-sectional configuration of one imaging element 2 of the plurality of imaging elements 2 arranged in a matrix in the pixel section 100. In the description of this application such as FIG. 2, a thickness direction (stacking direction) of the imaging element 2 is referred to as a Z-axis direction, and plane directions parallel to a stacking surface orthogonal to the Z-axis direction are referred to as an X-axis direction and a Y-axis direction. It is to be noted that the X-axis direction, the Y-axis direction, and the Z-axis direction are orthogonal to each other. FIG. 3 schematically illustrates an example of a horizontal cross-sectional configuration along a stacking surface (XY plane) direction orthogonal to the thickness direction (Z-axis direction) of the imaging element 2. (A) of FIG. 3 schematically illustrates an example of a horizontal cross-sectional configuration including an organic photoelectric converter 20, and (B) of FIG. 3 schematically illustrates an example of a horizontal cross-sectional configuration including a photoelectric converter 10. It is to be noted that FIG. 2 corresponds to a cross-section taken along a section line II-II illustrated in (A) of FIG. 3 as viewed from the direction of an arrow.

As illustrated in FIG. 2, the imaging element 2 is, for example, a so-called longitudinal spectral type imaging element including a structure in which one photoelectric converter 10 and one organic photoelectric converter 20 are stacked in the Z-axis direction that is the thickness direction. The imaging element 2 is a specific example corresponding to a “photoelectric conversion element” of the present disclosure. The imaging element 2 further includes an intermediate layer 40 and a multilayer wiring layer 30. The intermediate layer 40 is provided between the photoelectric converter 10 and the organic photoelectric converter 20, and the multilayer wiring layer 30 is provided on side opposite to the organic photoelectric converter 20 as viewed from the photoelectric converter 10. Furthermore, for example, one sealing film 51, a plurality of color filters (CFs) 52, one planarization film 53, and a plurality of on-chip lenses (OCLs) 54 provided corresponding one by one to the plurality of color filters 52 are stacked in the Z-axis direction in order from a position close to the organic photoelectric converter 20 on light incident side that is opposite to the photoelectric converter 10 as viewed from the organic photoelectric converter 20. The plurality of color filters 52 each include, for example, a color filter 52R that allows mainly a red color to pass therethrough, a color filter 52G that allows mainly a green color to pass therethrough, and a color filter 52B that allows mainly a blue color to pass therethrough. The imaging element 2 includes a plurality of color filters 52R, a plurality of color filters 52G, and a plurality of color filters 52B arranged in an arrangement pattern that is a so-called Bayer pattern, and obtains a color visible light image by receiving each of red light, green light, and blue light on the organic photoelectric converter 20. It is to be noted that FIG. 2 illustrates a state in which the color filters 52G and the color filters 52R are alternately arranged in the X-axis direction. In addition, the sealing film 51 and the planarization film 53 may each be provided common to a plurality of imaging elements 2.

### (Photoelectric Converter 10)

The photoelectric converter 10 is, for example, an indirect TOF (hereinafter referred to as iTOF) sensor that obtains a distance image (distance information) by time of flight (Time-of-Flight; TOF). The photoelectric converter 10 includes, for example, the semiconductor substrate 11, a photoelectric conversion region 12, a fixed electric charge layer 13, a pair of gate electrodes 14A and 14B, electric charge-voltage converters (FDs) 15A and 15B that are floating diffusion regions, an inter-pixel region light-shielding wall 16, and a through electrode 17.

The semiconductor substrate 11 is, for example, an n-type silicon (Si) substrate having a front surface 11A and a back surface 11B, and includes a p-well in a predetermined region. The front surface 11A is opposed to the multilayer wiring layer 30. The back surface 11B is a surface opposed to the intermediate layer 40. It is preferable that a fine recessed and projected structure be formed on the back surface 11B, which is effective in confining, inside the semiconductor substrate 11, light having a wavelength in an infrared light range (for example, from 880 nm to 1040 nm both inclusive) as a second wavelength range incident on the semiconductor substrate 11. It is to be noted that a similar fine recessed and projected structure may be also formed on the front surface 11A.

The photoelectric conversion region 12 is, for example, a photoelectric conversion element including a PIN (Positive Intrinsic Negative) type photodiode, and includes a pn junction formed in a predetermined region of the semiconductor substrate 11. The photoelectric conversion region 12 specifically detects and receives light having a wavelength in the infrared light range of light from a subject, generates electric charges corresponding to the amount of received light by photoelectric conversion, and accumulates the electric charges.

The fixed electric charge layer 13 is provided to cover the back surface 11B and the like of the semiconductor substrate 11. The fixed electric charge layer 13 has, for example, negative fixed electric charges to suppress generation of a dark current caused by an interface state of the back surface 11B that is a light-receiving surface of the semiconductor substrate 11. A hole accumulation layer is formed in proximity to the back surface 11B of the semiconductor substrate 11 by an electric field induced by the fixed electric charge layer 13. The hole accumulation layer suppresses generation of electrons from the back surface 11B. It is to be noted that the fixed electric charge layer 13 also includes a portion extending in the Z-axis direction between the inter-pixel region light-shielding wall 16 and the photoelectric conversion region 12. The fixed electric charge layer 13 is preferably formed with use of an insulating material. Specific examples of a constituent material of the fixed electric charge layer 13 include hafnium oxide (HfOₓ), aluminum oxide (AlOₓ), zirconium oxide (ZrOₓ), tantalum oxide (TaOₓ), titanium oxide (TiOₓ), lanthanum oxide (LaOₓ), praseodymium oxide (PrOₓ), cerium oxide (CeOₓ), neodymium oxide (NdOₓ), promethium oxide (PmOₓ), samarium oxide (SmOₓ), europium oxide (EuOₓ), gadolinium oxide (GdOₓ), terbium oxide (TbOₓ), dysprosium oxide (DyOₓ), holmium oxide (HoOₓ), thulium oxide (TmOₓ), ytterbium oxide (YbOₓ), lutetium oxide (LuOₓ), yttrium oxide (YOₓ), hafnium nitride (HfNₓ), aluminum nitride (AlNₓ), hafnium oxynitride (HfOₓN_{y}), aluminum oxynitride (AlOₓN_{y}), and the like.

The pair of gate electrodes 14A and 14B are respectively included in portions of transfer transistors (TG) 141A and 141B, and extend in the Z-axis direction from the front surface 11A to the photoelectric conversion region 12, for example. The TG 141A and the TG 141B respectively transfer electric charges accumulated in the photoelectric conversion region 12 to the pair of FDs 15A and 15B in accordance with a drive signal applied to each of the gate electrodes 14A and 14B.

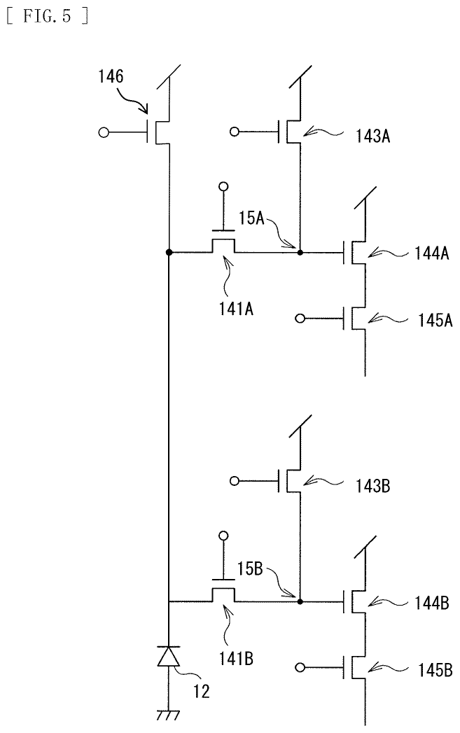

The pair of FDs 15A and 15B are respectively floating diffusion regions that convert electric charges transferred from the photoelectric conversion region 12 through the TGs 141A and 141B including the gate electrodes 14A and 14B into electric signals (e.g., voltage signals), and output the electric signals. The FDs 15A and 15B are respectively coupled to reset transistors (RSTs) 143A and 143B, and are respectively coupled to the vertical signal line Lsig (FIG. 1) through amplification transistors (AMPs) 144A and 144B and selection transistors (SELs) 145A and 145B, as illustrated in FIG. 5 to be described later.

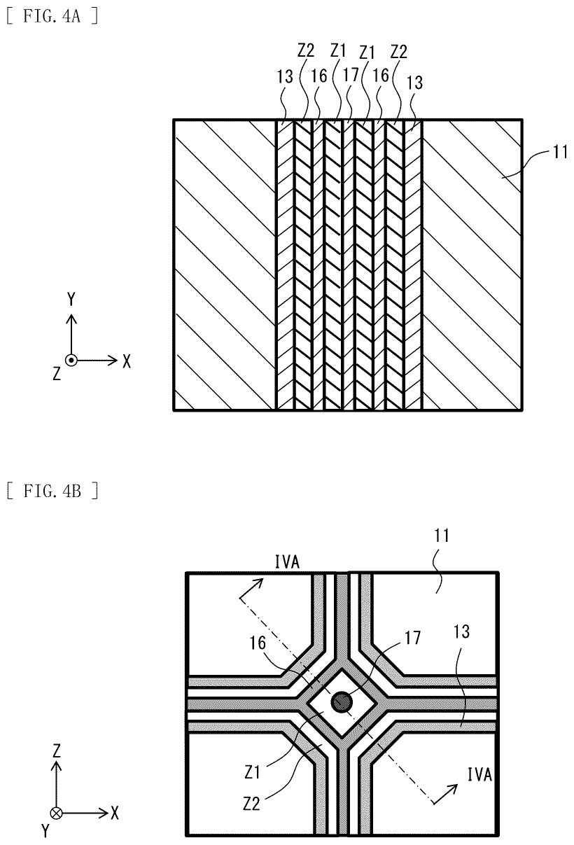

FIG. 4A is an enlarged cross-sectional view taken along an Z axis of the inter-pixel region light-shielding wall 16 that surrounds the through electrode 17 in the imaging element 2 illustrated in FIG. 2, and FIG. 4B is an enlarged cross-sectional view taken along an XY plane of the inter-pixel region light-shielding wall 16 that surrounds the through electrode 17. FIG. 4A illustrates a cross-section taken along a line IVA-IVA illustrated in FIG. 4B as viewed from the direction of an arrow. The inter-pixel region light-shielding wall 16 is provided in boundary portions with other adjacent imaging elements 2 in the XY plane. The inter-pixel region light-shielding wall 16 includes, for example, a portion extending along an XZ plane and a portion extending along a YZ plane, and is provided to surround the photoelectric conversion region 12 of each imaging element 2. In addition, the inter-pixel region light-shielding wall 16 may be provided to surround the through electrode 17. This makes it possible to suppress oblique incidence of unnecessary light onto the photoelectric conversion regions 12 of adjacent imaging elements 2 and prevent color mixture.

The inter-pixel region light-shielding wall 16 includes, for example, a material that includes at least one kind of elemental metals, metal alloys, metal nitrides, and metal silicides that have a light-shielding property. More specific constituent materials of the inter-pixel region light-shielding wall 16 include Al (aluminum), Cu (copper), Co (cobalt), W (tungsten), Ti (titanium), Ta (tantalum), Ni (nickel), Mo (molybdenum), Cr (chromium), Ir (iridium), platiniridium, TiN (titanium nitride), a tungsten-silicon compound, and the like. It is to be noted that the constituent material of the inter-pixel region light-shielding wall 16 is not limited to metal materials, and the inter-pixel region light-shielding wall 16 may be formed with use of graphite. In addition, the inter-pixel region light-shielding wall 16 is not limited to an electrically conductive material, and may include an electrically non-conductive material having a light-shielding property such as an organic material. In addition, for example, an insulating layer Z1 including an insulating material such as SiOx (silicon oxide) and aluminum oxide may be provided between the inter-pixel region light-shielding wall 16 and the through electrode 17. Alternatively, a gap may be provided between the inter-pixel region light-shielding wall 16 and the through electrode 17 to insulate the inter-pixel region light-shielding wall 16 and the through electrode 17 from each other. It is to be noted that the insulating layer Z1 may not be provided in a case where the inter-pixel region light-shielding wall 16 includes an electrically non-conductive material. Furthermore, an insulating layer Z2 may be provided outside the inter-pixel region light-shielding wall 16, that is, between the inter-pixel region light-shielding wall 16 and the fixed electric charge layer 13. The insulating layer Z2 includes, for example, an insulating material such as SiOx (silicon oxide) and aluminum oxide. Alternatively, a gap may be provided between the inter-pixel region light-shielding wall 16 and the fixed electric charge layer 13 to insulate the inter-pixel region light-shielding wall 16 and the fixed electric charge layer 13 from each other. In a case where the inter-pixel region light-shielding wall 16 includes an electrically conductive material, electrical insulation between the inter-pixel region light-shielding wall 16 and the semiconductor substrate 11 is secured by the insulating layer Z2. In addition, in a case where the inter-pixel region light-shielding wall 16 is provided to surround the through electrode 17 and the inter-pixel region light-shielding wall 16 includes an electrically conductive material, electrical insulation between the inter-pixel region light-shielding wall 16 and the through electrode 17 is secured by the insulating layer Z1.

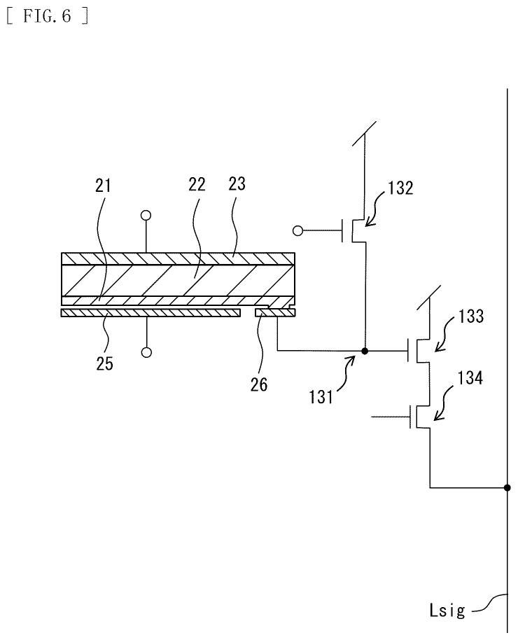

The through electrode 17 is, for example, a coupling member that electrically couples a readout electrode 26 of the organic photoelectric converter 20 to an FD 131 and an AMP 133 (see FIG. 6 to be described later). The readout electrode 26 is provided on side of the back surface 11B of the semiconductor substrate 11, and the FD 131 and the AMP 133 are provided on the front surface 11A of the semiconductor substrate 11. The through electrode 17 is, for example, a transmission path where signal electric charges generated in the organic photoelectric converter 20 are transmitted and a voltage that drives an electric charge accumulation electrode 25 is transmitted. For example, it is possible to provide the through electrode 17 to extend in the Z-axis direction from the readout electrode 26 of the organic photoelectric converter 20 to the multilayer wiring layer 30 through the semiconductor substrate 11. The through electrode 17 is able to favorably transfer signal electric charges generated in the organic photoelectric converter 20, which is provided on the side of the back surface 11B of the semiconductor substrate 11, to side of the front surface 11A of the semiconductor substrate 11. The fixed electric charge layer 13 and an insulating layer 41 are provided around the through electrode 17, which electrically insulates the through electrode 17 and a p-well region of the semiconductor substrate 11 from each other.

It is possible to form the through electrode 17 with use of one or more kinds of metal materials such as aluminum (Al), tungsten (W), titanium (Ti), cobalt (Co), platinum (Pt), palladium (Pd), copper (Cu), hafnium (Hf), and tantalum (Ta), in addition to a silicon material doped with an impurity such as PDAS (Phosphorus Doped Amorphous Silicon).

### (Multilayer Wiring Layer 30)

The multilayer wiring layer 30 includes, for example, a readout circuit including the TGs 141A and 141B, the RSTs 143A and 143B, the AMPs 144A and 144B, the SELs 145A and 145B, and the like.

### (Intermediate Layer 40)

The intermediate layer 40 may include, for example, the insulating layer 41, and an optical filter 42 and an inter-pixel region light-shielding film 43 that are embedded in the insulating layer 41. The insulating layer 41 includes, for example, a monolayer film including one kind of inorganic insulating materials such as silicon oxide (SiOₓ), silicon nitride (SiNₓ), and silicon oxynitride (SiON), or a stacked film including two or more kinds thereof. Furthermore, an organic insulating material such as polymethyl methacrylate (PMMA), polyvinyl phenol (PVP), polyvinyl alcohol (PVA), polyimide, polycarbonate (PC), polyethylene terephthalate (PET), polystyrene, N-2(aminoethyl)3-aminopropyltrimethoxysilane (AEAPTMS), 3-mercaptopropyl trimethoxysilane (MPTMS), tetraethoxysilane (TEOS), and octadecyltrichlorosilane (OTS) may be used as a material included in the insulating layer 41.

The optical filter 42 has a transmission band in the infrared light range where photoelectric conversion is performed in the photoelectric conversion region 12. That is, light having a wavelength in the infrared light range, that is, infrared light passes through the optical filter 42 more easily than light having a wavelength in a visible light range (e.g., a wavelength of 400 nm to 700 nm both inclusive), that is, visible light. Specifically, it is possible to configure the optical filter 42 with use of an organic material, for example, and the optical filter 42 absorbs at least a portion of light having a wavelength in the visible light range while selectively allowing light in the infrared light range to pass therethrough. The optical filter 42 includes, for example, an organic material such as a phthalocyanine derivative.

The inter-pixel region light-shielding film 43 is provided in boundary portions with other adjacent imaging elements 2 in the XY plane. The inter-pixel region light-shielding film 43 includes a portion extending along the XY plane, and is provided to surround the photoelectric conversion region 12 of each imaging element 2. The inter-pixel region light-shielding film 43 suppresses oblique incidence of unnecessary light onto the photoelectric conversion regions 12 of adjacent imaging elements 2 and prevents color mixture, as with the inter-pixel region light-shielding wall 16. It is to be noted that the inter-pixel region light-shielding film 43 may be provided as necessary; therefore, the imaging element 2 may not include the inter-pixel region light-shielding film 43.

### (Organic Photoelectric Converter 20)

The organic photoelectric converter 20 includes, for example, the readout electrode 26, a semiconductor layer 21, an organic photoelectric conversion layer 22, and an upper electrode 23 that are stacked in order from a position close to the photoelectric converter 10. The organic photoelectric converter 20 further includes an insulating layer 24 and the electric charge accumulation electrode 25, The insulating layer 24 is provided below the semiconductor layer 21, and the electric charge accumulation electrode 25 is provided to be opposed to the semiconductor layer 21 with the insulating layer 24 interposed therebetween. Two of a plurality of electric charge accumulation electrodes 25 are allocated to, for example, each on-chip lens 54 and each color filter 52. Two electric charge accumulation electrode 25 allocated to each on-chip lens 54 and each color filter 52 are disposed apart from each other and adjacent to each other, for example, in the X-axis direction. The plurality of electric charge accumulation electrodes 25 and the readout electrode 26 are apart from each other, and are provided at the same level, for example. The readout electrode 26 is in contact with an upper end of the through electrode 17. It is to be noted that the upper electrode 23, the organic photoelectric conversion layer 22, and the semiconductor layer 21 may each be provided common to some imaging elements 2 of the plurality of imaging elements 2 (FIG. 2) in the pixel section 100, or may each be provided common to all the plurality of imaging elements 2 in the pixel section 100. The same applies to other embodiments, modification examples, and the like to be described after the present embodiment.

It is to be noted that another organic layer may be provided each between the organic photoelectric conversion layer 22 and the semiconductor layer 21 and between the organic photoelectric conversion layer 22 and the upper electrode 23.

The readout electrode 26, the upper electrode 23, and the electric charge accumulation electrode 25 each include an electrically conductive film having light transmissivity, and include, for example, ITO (indium tin oxide). However, in addition to ITO, a tin oxide (SnOₓ)-based material doped with a dopant, or a zinc oxide-based material obtained by doping zinc oxide (ZnO) with a dopant may be used as constituent materials of the readout electrode 26, the upper electrode 23, and the electric charge accumulation electrode 25. Examples of the zinc oxide-based material include aluminum zinc oxide (AZO) doped with aluminum (Al) as a dopant, gallium zinc oxide (GZO) doped with gallium (Ga), and indium zinc oxide (IZO) doped with indium (In). In addition, as the constituent materials of the readout electrode 26, the upper electrode 23, and the electric charge accumulation electrode 25, CuI, InSbO₄, ZnMgO, CuInO₂, MgIN₂O₄, CdO, ZnSnO₃, TiO₂, or the like may be used. Furthermore, a spinel oxide, an oxide having a YbFe₂O₄ structure may be used.

The organic photoelectric conversion layer 22 converts light energy into electrical energy, and is formed including two or more kinds of organic materials functioning as a p-type semiconductor and a n-type semiconductor. The p-type semiconductor relatively functions as an electron donor (a donor), and the n-type semiconductor relatively functions as an electron acceptor (an acceptor). The organic photoelectric conversion layer 22 has a bulk heterojunction structure in a layer. The bulk heterojunction structure is a p/n junction surface that is formed by mixing the p-type semiconductor and the n-type semiconductor, and excitons generated upon absorption of light are dissociated into electrons and holes at the p/n junction surface.

The organic photoelectric conversion layer 22 may further include, in addition to the p-type semiconductor and the n-type semiconductor, three kinds of so-called dye materials that photoelectrically convert light in a predetermined wavelength band while allowing light in another wavelength band to pass therethrough. The p-type semiconductor, the n-type semiconductor, and the dye materials preferably have absorption maximum wavelengths different from each other. This makes it possible to absorb wavelengths in a visible light region in a wide range.

For example, various kinds of organic semiconductor materials described above are mixed, and spin coating technology is used, thereby making it possible to form the organic photoelectric conversion layer 22. In addition, the organic photoelectric conversion layer 22 may be formed with use of a vacuum deposition method, printing technology, or the like, for example.

As a material included in the semiconductor layer 21, it is preferable to use a material having a large band gap value (e.g., a band gap value of 3.0 eV or greater) and having higher mobility than a material included in the organic photoelectric conversion layer 22. Specific materials thereof may include organic semiconductor materials such as oxide semiconductor materials including IGZO and the like, transition metal dichalcogenide, silicon carbide, diamond, graphene, carbon nanotubes, a condensed polycyclic hydrocarbon compound, and a condensed heterocyclic compound.

The electric charge accumulation electrode 25 forms a kind of capacitor together with the insulating layer 24 and the semiconductor layer 21, and accumulates electric charges generated in the organic photoelectric conversion layer 22 in a portion of the semiconductor layer 21, e.g., a region portion, corresponding to the electric charge accumulation electrode 25 with the insulating layer 24 interposed therebetween, of the semiconductor layer 21. In the present embodiment, one electric charge accumulation electrode 25 is provided corresponding to one photoelectric conversion region 12, one color filter 52, and one on-chip lens 54. The electric charge accumulation electrode 25 is coupled to the vertical drive circuit 111, for example.

It is possible to form the insulating layer 24 with use of, for example, an inorganic insulating material and an organic insulating material, as with the insulating layer 41.

The organic photoelectric converter 20 detects a portion or the entirety of light having a wavelength in the visible light range, as described above. In addition, it is desirable that the organic photoelectric converter 20 not have sensitivity to light in the infrared light range.

In the organic photoelectric converter 20, light incident from side of the upper electrode 23 is absorbed by the organic photoelectric conversion layer 22. Excitons (electron-hole pairs) thereby generated move to an interface between the electron donor and the electron acceptor included in the organic photoelectric conversion layer 22, and the excitons are dissociated, that is, the excitons are dissociated into electrons and holes. Electric charges generated herein, that is, electrons and holes move to the upper electrode 23 or the semiconductor layer 21 by diffusion resulting from a difference in concentration between carriers and an internal electric field resulting from a potential difference between the upper electrode 23 and the electric charge accumulation electrode 25, and are detected as photocurrent. For example, it is assumed that the readout electrode 26 is at a positive potential and the upper electrode 23 is at a negative potential. In this case, holes generated by photoelectric conversion in the organic photoelectric conversion layer 22 move to the upper electrode 23. Electrons generated by photoelectric conversion in the organic photoelectric conversion layer 22 are drawn to the electric charge accumulation electrode 25, and are accumulated in the portion of the semiconductor layer 21, e.g., the region portion, corresponding to the electric charge accumulation electrode 25 with the insulating layer 24 interposed therebetween, of the semiconductor layer 21.

Electric charges (e.g., electrons) accumulated in the region portion, corresponding to the electric charge accumulation electrode 25 with the insulating layer 24 interposed therebetween, of the semiconductor layer 21 are read out as follows. Specifically, a potential V26 is applied to the readout electrode 26, and a potential V25 is applied to the electric charge accumulation electrode 25. Herein, the potential V26 is higher than the potential V25 (V25<V26). By doing so, the electrons accumulated in the region portion, corresponding to the electric charge accumulation electrode 25, of the semiconductor layer 21 are transferred to the readout electrode 26.

As described above, the semiconductor layer 21 is provided below the organic photoelectric conversion layer 22, and electric charges (e.g., electrons) are accumulated in the region portion, corresponding to the electric charge accumulation electrode 25 with the insulating layer 24 interposed therebetween, of the semiconductor layer 21, thereby achieving the following effects. That is, as compared with a case where electric charges (e.g., electrons) are accumulated in the organic photoelectric conversion layer 22 without providing the semiconductor layer 21, it is possible to prevent recombination of holes and electrons during electric charge accumulation, and increase transfer efficiency of accumulated electric charges (e.g., electrons) to the readout electrode 26, and it is possible to suppress generation of a dark current. A case where electrons are read out is described above as an example; however, holes may be read out. In a case where holes are read out, the potentials described above are described as potentials sensed by holes.

### (Readout Circuit of Photoelectric Converter 10)

FIG. 5 is a circuit diagram illustrating an example of a readout circuit of the photoelectric converter 10 included in the imaging element 2 illustrated in FIG. 2.

The readout circuit of the photoelectric converter 10 includes, for example, the TGs 141A and 141B, an OFG 146, the FDs 15A and 15B, the RSTs 143A and 143B, the AMPs 144A and 144B, and the SELs 145A and 145B.

The TGs 141A and 141B are respectively coupled between the photoelectric conversion region 12 and the FD 15A and between the photoelectric conversion region 12 and the FD 15B. A drive signal is applied to the gate electrodes 14A and 14B of the TGs 141A and 141B to turn the TGs 141A and 141B to an active state, which turns transfer gates of the TGs 141A and 141B to an electrically conductive state. As a result, signal electric charges converted in the photoelectric conversion region 12 are transferred to the FDs 15A and 15B respectively through the TGs 141A and 141B.

The OFG 146 is coupled between the photoelectric conversion region 12 and a power supply. A drive signal is applied to a gate electrode of the OFG 146 to turn the OFG 146 to the active state, which turns the OFG 146 to the electrically conductive state. As a result, signal electric charges converted in the photoelectric conversion region 12 are discharged to the power supply through the OFG 146.

The FDs 15A and 15B are respectively coupled between the TG 141A and AMP 144A and between the TG 141B and the AMP 144B. The FDs 15A and 15B respectively perform electric charge-voltage conversion of the signal electric charges transferred from the TGs 141A and 141B into voltage signals, and output the voltage signals to the AMPs 144A and 144B.

The RSTs 143A and 143B are respectively coupled between the FD 15A and the power supply and between the FD 15B and the power supply. A drive signal is applied to gate electrodes of the RSTs 143A and 143B to turn the RSTs 143A and 143B to the active state, which turns reset gates of the RSTs 143A and 143B to the electrically conductive state. As a result, potentials of the FDs 15A and 15B are reset to a power supply level.

The AMPs 144A and 144B respectively include gate electrodes coupled to the FDs 15A and 15B, and include drain electrodes coupled to the power supply. The AMPs 144A and 144B are input sections of readout circuits of voltage signals held by the FDs 15A and 15B, that is, so-called source follower circuits. That is, the AMPs 144A and 144B respectively have source electrodes coupled to the vertical signal line Lsig through the SELs 145A and 145B, thereby configuring source follower circuits with a constant current source coupled to one end of the vertical signal line Lsig.

The SELs 145A and 145B are respectively coupled between the source electrode of the AMP 144A and the vertical signal line Lsig and between the source electrode of the AMP 144B and the vertical signal line Lsig. A drive signal is applied to the respective gate electrodes of the SELs 145A and 145B to turn the SELs 145A and 145B to the active state, which turns the SELs 145A and 145B to the electrically conductive state to turn the imaging element 2 to a selection state. Accordingly, readout signals (pixel signals) outputted from the AMPs 144A and 144B are respectively outputted to the vertical signal line Lsig through the SELs 145A and 145B.

In the solid-state imaging device 1, a light pulse in an infrared range is applied to a subject, and the photoelectric conversion region 12 of the photoelectric converter 10 receives the light pulse reflected from the subject. In the photoelectric conversion region 12, a plurality of electric charges are generated by incidence of the light pulse in the infrared range. The plurality of electric charges generated in the photoelectric conversion region 12 are alternately distributed to the FD 15A and the FD 15B by alternately supplying a drive signal to the pair of gate electrodes 14A and 14B over equal time intervals. A shutter phase of the drive signal to be applied to the gate electrodes 14A and 14B is changed with respect to the light pulse to be applied, which causes the amount of electric charges accumulated in the FD 15A and the amount of electric charges accumulated in the FD 15B to be phase-modulated values. A round trip time of the light pulse is estimated by demodulating these values, thereby determining a distance between the solid-state imaging device 1 and the subject.

### (Readout Circuit of Organic Photoelectric Converter 20)

FIG. 6 is a circuit diagram illustrating an example of the readout circuit of the organic photoelectric converter 20 included in the imaging element 2 illustrated in FIG. 2.

The readout circuit of the organic photoelectric converter 20 includes, for example, the FD 131, a RST 132, the AMP 133, and a SEL 134.

The FD 131 is coupled between the readout electrode 26 and the AMP 133. The FD 131 performs electric charge-voltage conversion of signal electric charges transferred from the readout electrode 26 into voltage signals, and outputs the voltage signals to the AMP 133.

The RST 132 is coupled between the FD 131 and the power supply. A drive signal is applied to a gate electrode of the RST 132 to turn the RST 132 to the active state, which turns a reset gate of the RST 132 to the electrically conductive state. As a result, a potential of the FD 131 is reset to the power supply level.

The AMP 133 includes a gate electrode coupled to the FD 131 and a drain electrode coupled to the power supply. A source electrode of the AMP 133 is coupled to the vertical signal line Lsig through the SEL 134.

The SEL 134 is coupled between the source electrode of the AMP 133 and the vertical signal line Lsig. A drive signal is applied to a gate electrode of the SEL 134 to turn the SEL 134 to the active state, which turns the SEL 134 to the electrically conductive state to turn the imaging element 2 to the selection state. Thus, a readout signal (a pixel signal) outputted from the AMP 133 is outputted to the vertical signal line Lsig through the SEL 134.

### (Planar Configuration Example of Imaging Element 2)

FIG. 3 illustrates a total of four imaging elements 2 arranged two by two in the X-axis direction and the Y-axis direction. As illustrated in (B) of FIG. 3, the photoelectric converters 10 in the four imaging elements 2 each include one pixel IR as a second photoelectric conversion portion that detects infrared light and photoelectrically converts the infrared light. It is to be noted that, in (B) of FIG. 3, to distinguish four pixels IR from each other, reference signs IR1 to IR4 are assigned to the four pixels IR for the sake of convenience. The pixels IR1 to IR4 each have a length WX2 in the X-axis direction and a length WY2 in the Y-axis direction. The length WX2 and the length WY2 may be substantially equal to each other or may be substantially different from each other. It is to be noted that “substantially” means a concept not including a slight difference such as manufacturing error. In addition, the pixels IR1 to IR4 each have one photoelectric conversion region 12. That is, one imaging element 2 has one photoelectric conversion region 12.

Meanwhile, the organic photoelectric converters 20 in the four imaging elements 2 each include four pixel groups G1 to G4 that detect visible light, as illustrated in (A) of FIG. 3. In each imaging element 2, the pixel groups G1 to G4 are arranged in two rows by two columns, and are disposed to occupy a region corresponding to one pixel IR in the Z-axis direction. The pixel groups G1 to G4 each include four pixels P as first photoelectric conversion portions arranged in an arrangement pattern that is a so-called Bayer pattern. Specifically, the pixel groups G1 to G4 each include one red pixel PR, two green pixels PG, and one blue pixel PB as the four pixels P. The red pixel PR detects red light and photoelectrically converts the red light. The green pixel PG detects green light and photoelectrically converts the green light. The blue pixel PB detects blue light and photoelectrically converts the blue light. Here, the two green pixels PG are disposed at positions diagonal to each other in a rectangular region occupied by each of the pixel groups G1 to G4. Accordingly, a first green pixel PG of the two green pixels PG is disposed, for example, adjacent to the red pixel PR in the X-axis direction and adjacent to the blue pixel PB in the Y-axis direction. A second green pixel PG of the two green pixels PG is disposed, for example, adjacent to the red pixel PR in the Y-axis direction and adjacent to the blue pixel PB in the X-axis direction.

Thus, in each of imaging elements 2, sixteen pixels P arranged in four rows by four columns are periodically arranged. Each pixel P has a length WX1 in the X-axis direction and has a length WY1 in the Y-axis direction. That is, the length WX1 is a first arrangement period of a plurality of pixels P in the X-axis direction, and the length WY1 is a second arrangement period of the plurality of pixels P in the Y-axis direction. The length WX1 and the length WY1 may be substantially equal to each other or may be substantially different from each other. Here, n times (n is a natural number) the length WX1 in the X-axis direction is substantially equal to the length WX2 of the pixel IR in the X-axis direction, and n times (n is a natural number) the length WY1 in the Y-axis direction is substantially equal to the length WY2 of the pixel IR in the Y-axis direction. In a case of a configuration example illustrated in FIGS. 2 and 3, the natural number n is specifically 4.

In addition, one on-chip lens 54, one color filter 52, and two electric charge accumulation electrodes 25 are allocated to each of the red pixel PR, the green pixel PG, and the blue pixel PB. That is, the red pixel PR includes a sub-pixel PR1 and a sub-pixel PR2 each including one electric charge accumulation electrode 25 as a constituent unit. The sub-pixel PR1 and the sub-pixel PR2 are disposed adjacent to each other in the X-axis direction, for example. Likewise, the green pixel PG includes a sub-pixel PG1 and a sub-pixel PG2 each including one electric charge accumulation electrode 25 as a constituent unit, and the blue pixel PB includes a sub-pixel PB1 and a sub-pixel PB2 each including one electric charge accumulation electrode 25 as a constituent unit. The sub-pixel PG1 and the sub-pixel PG2 are disposed adjacent to each other in the X-axis direction, and the sub-pixel PB1 and the sub-pixel PB2 are disposed adjacent to each other in the X-axis direction. Accordingly, it is possible to use each of the red pixel PR, the green pixel PG, and the blue pixel PB as an image plane phase difference pixel. That is, it is possible for the organic photoelectric converter 20 to generate a pixel signal for performing autofocusing by the image plane phase difference pixel.

In addition, as illustrated in FIG. 3, it is preferable that arrangement patterns of a plurality of pixels P corresponding to the pixels IR in a plurality of imaging elements 2 provided in the pixel section 100 of the solid-state imaging device 1 be all the same.

### [Workings and Effects of Solid-State Imaging Device 1]

The solid-state imaging device 1 according to the present embodiment includes the organic photoelectric converter 20, the optical filter 42, and the photoelectric converter 10 that are stacked in order from incident side. The organic photoelectric converter 20 detects light having a wavelength in the visible light range and photoelectrically convert the light. The optical filter 42 has a transmission band in the infrared light range. The photoelectric converter 10 detects light having a wavelength in the infrared light range and photoelectrically converts the light. This makes it possible to simultaneously obtain a visible light image and an infrared light image at the same position in an in-plane direction of the XY plane. The visible light image is configured by a red light signal, a green light signal, and a blue light signal respectively obtained from the red pixel PR, the green pixel PG, and the blue pixel PB, and the infrared light image uses infrared light signals obtained from all the plurality of pixels P. It is therefore possible to achieve high integration in the in-plane direction of the XY plane.

Furthermore, the photoelectric converter 10 includes the pair of TGs 141A and 141B, and the FDs 15A and 15B, which makes it possible to obtain an infrared light image as a distance image including information about a distance to a subject. Therefore, according to the solid-state imaging device 1 according to the present embodiment, it is possible to obtain both a visible light image having high resolution and an infrared light image having depth information.

In addition, in the imaging element 2 according to the present embodiment, n times (n is a natural number) the length WX1 that is the first arrangement period of the plurality of pixels P in the X-axis direction (an arrangement pitch of the pixels P in the X-axis direction) is substantially equal to the length WX2 of one pixel IR in the X-axis direction, and n times (n is a natural number) the length WY1 that is the second arrangement period of the plurality of pixels P in the Y-axis direction (an arrangement pitch of the pixels P in the Y-axis direction) is substantially equal to the length WY2 of one pixel IR in the Y-axis direction. Accordingly, as compared with a case where the dimension of the pixel IR is different from a multiple of the dimension of the plurality of pixels P, the plurality of pixels P is more equally allocated to one pixel IR. For example, it is possible to make arrangement patterns of the plurality of pixels P corresponding to the pixels IR in the plurality of imaging elements 2 provided in the pixel section 100 of the solid-state imaging device 1 equal to each other. That is, light amount distributions of infrared light detected by the pixels IR in the respective imaging elements 2 become more approximate toward a direction where the light amount distributions become substantially equal to each other. This makes it easy to reduce variations in photoelectric conversion characteristics among the plurality of imaging elements 2.

Specifically, in the imaging element 2 according to the present embodiment, the pixel groups G1 to G4 that each include four pixels P arranged in a Bayer pattern and having the same layout are equally arranged. This makes it easy to reduce variations in photoelectric conversion characteristics also in each imaging element 2.

In addition, in the pixel P1 according to the present embodiment, the organic photoelectric converter 20 includes the insulating layer 24 and the electric charge accumulation electrode 25, in addition to the structure in which the readout electrode 26, the semiconductor layer 21, the organic photoelectric conversion layer 22, and the upper electrode 23 are stacked in order. The insulating layer 24 is provided below the semiconductor layer 21, and the electric charge accumulation electrode 25 is provided to be opposed to the semiconductor layer 21 with the insulating layer 24 interposed therebetween. This makes it possible to accumulate electric charges generated by photoelectric conversion in the organic photoelectric conversion layer 22 in the portion of the semiconductor layer 21, e.g., the region portion, corresponding to the electric charge accumulation electrode 25 with the insulating layer 24 interposed therebetween, of the semiconductor layer 21. This makes it possible to achieve removal of electric charges in the semiconductor layer 21, that is, full depletion of the semiconductor layer 21 upon start of exposure, for example. As a result, it is possible to reduce kTC noise, which makes it possible to suppress a decrease in image quality caused by random noise. Furthermore, as compared with a case where electric charges (e.g., electrons) are accumulated in the organic photoelectric conversion layer 22 without providing the semiconductor layer 21, it is possible to prevent recombination of holes and electrons during electric charge accumulation, and increase transfer efficiency of accumulated electric charges (e.g., electrons) to the readout electrode 26, and it is possible to suppress generation of a dark current.

Furthermore, in the imaging element 2 according to the present embodiment, a plurality of on-chip lens 54, the color filters 52 of a plurality of colors, a plurality of electric charge accumulation electrodes 25 are provided, corresponding to one photoelectric conversion region 12, at positions overlapping each other in the Z-axis direction. Accordingly, it is possible to reduce a difference in infrared light detection sensitivity, as compared with a case where only the color filter 52 of the same color is provided at a position corresponding to one photoelectric conversion region 12 in the Z-axis direction. In general, transmittance of infrared light passing through the color filter 52 differs depending on colors of the color filters 52. Accordingly, intensity of infrared light reaching the photoelectric conversion region 12 differs among a case where the infrared light passes through the red color filter 52R, a case where the infrared light passes through the green color filter 52G, and a case where the infrared light passes through the blue color filter 52B. This causes variations in infrared light detection sensitivity in each of the plurality of imaging elements 2. In that respect, according to the imaging element 2 according to the present embodiment, infrared light having passed through each of the color filters 52 of the plurality of colors enters the photoelectric conversion region 12. This makes it possible to reduce a difference in infrared light detection sensitivity among the plurality of imaging elements 2.

It is to be noted that in the present embodiment, the color filters 52 of red, green, and blue are included, and respectively receive red light, green light, and blue light to obtain a color visible light image; however, a monochromatic visible light image may be obtained without providing the color filter 52.

### First Modification Example of First Embodiment

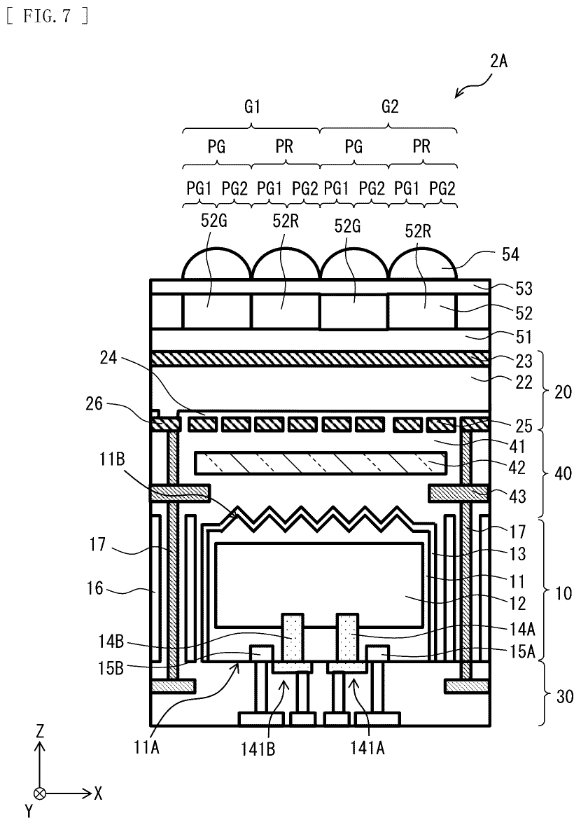

FIG. 7 schematically illustrates an example of a vertical cross-sectional configuration along the thickness direction of an imaging element 2A according to a first modification example (Modification Example 1-1) of the first embodiment. In the present disclosure, as with the imaging element 2A illustrated in FIG. 7, the semiconductor layer 21 may not be provided. In the imaging element 2A illustrated in FIG. 7, the organic photoelectric conversion layer 22 is coupled to the readout electrode 26, and the electric charge accumulation electrode 25 is provided to be opposed to the organic photoelectric conversion layer 22 with the insulating layer 24 interposed therebetween. In a case of such a configuration, electric charges generated by photoelectric conversion in the organic photoelectric conversion layer 22 are accumulated in the organic photoelectric conversion layer 22. Even in this case, upon photoelectric conversion in the organic photoelectric conversion layer 22, a kind of capacitor is formed by the organic photoelectric conversion layer 22, the insulating layer 24, and the electric charge accumulation electrode 25. This makes it possible to achieve removal of electric charges in the organic photoelectric conversion layer 22, that is, full depletion of the organic photoelectric conversion layer 22 upon start of exposure, for example. As a result, it is possible to reduce kTC noise, which makes it possible to suppress a decrease in image quality caused by random noise.

### Second Modification Example of First Embodiment

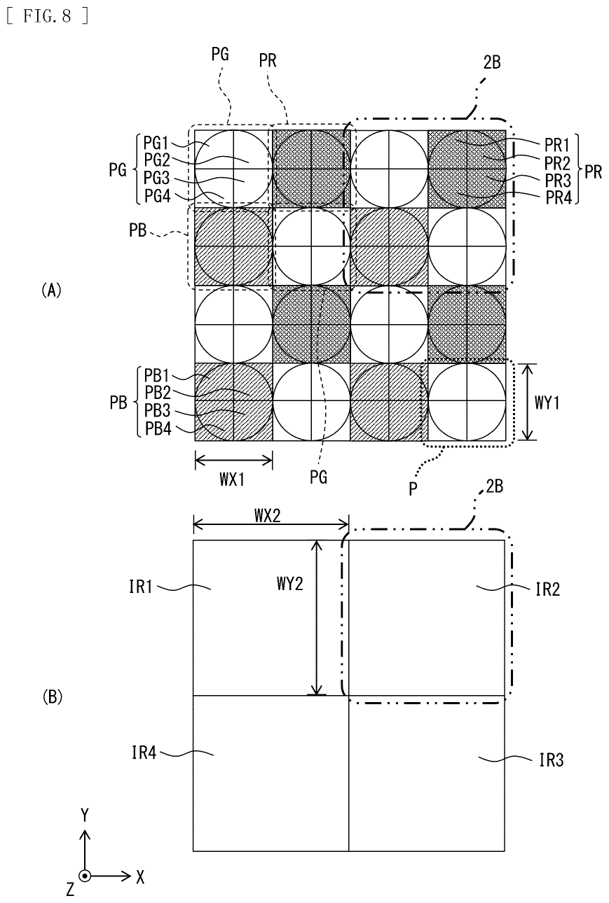

FIG. 8 schematically illustrates a configuration example of a horizontal cross-section of an imaging element 2B according to a second modification example (Modification Example 1-2) of the first embodiment. (A) of FIG. 8 and (B) of FIG. 8 respectively correspond to (A) of FIG. 3 and (B) of FIG. 3 that illustrate the imaging element 2 according to the first embodiment described above.

In the imaging element 2B, four pixels P arranged in two rows by two columns are allocated to one pixel IR. Specifically, one red pixel PR, two green pixels PG, and one blue pixel PB arranged in a Bayer pattern are allocated to each of the pixels IR1 to IR4. The pixels P (PR, PG, and PB) each have the length WX1 in the X-axis direction and the length WY1 in the Y-axis direction. In the present modification example, twice the length WX1 of the pixel P is substantially equal to the length WX2 of the pixel IR, and twice the length WY1 of the pixel P is substantially equal to the length WY2 of the pixel IR.

In addition, in the imaging element 2B, each of the pixels P (PR, PG, and PB) is divided into four, and individually detect visible light. Specifically, the red pixel PR includes sub-pixels PR1 to PR4. The green pixel PG includes sub-pixels PG1 to PG4. The blue pixel PR includes sub-pixels PB1 to PB4. One electric charge accumulation electrode 25 is allocated to each sub-pixel.

### Third Modification Example of First Embodiment

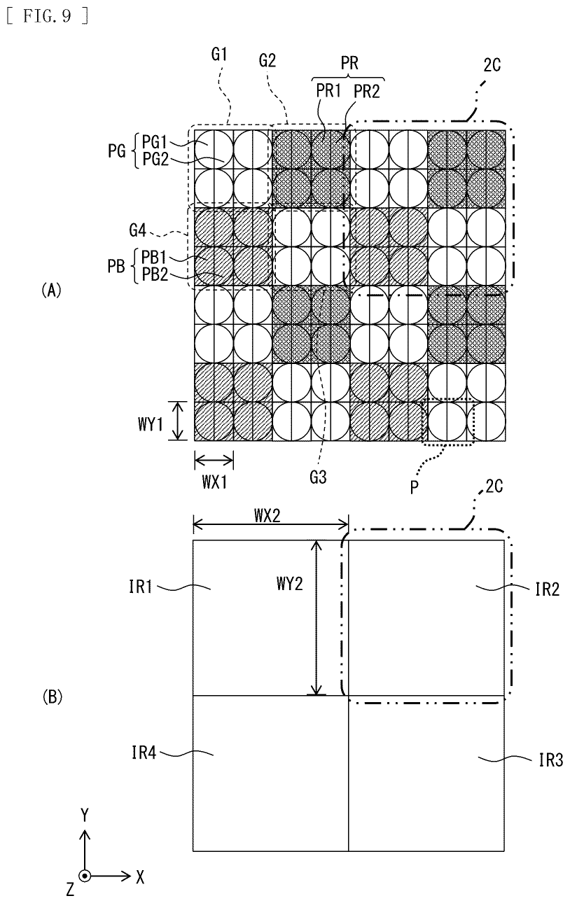

FIG. 9 schematically illustrates a configuration example of a horizontal cross-section of an imaging element 2C according to a third modification example (Modification Example 1-3) of the first embodiment. (A) of FIG. 9 and (B) of FIG. 9 respectively correspond to (A) of FIG. 3 and (B) of FIG. 3 that illustrate the imaging element 2 according to the first embodiment described above.

In the imaging element 2C, four pixel groups G1 to G4 arranged in two rows by two columns are allocated to one pixel IR. Four pixels P arranged in two rows by two columns are allocated to each of the four pixel groups G1 to G4. Note that only green pixels PG are allocated to the pixel group G1. Only red pixels PR are allocated to the pixel group G2. Only green pixels PG are allocated to the pixel group G3. Only blue pixels PB are allocated to the pixel group G4. Except for this point, the configuration of the imaging element 2C is substantially the same as the configuration of the imaging element 2 according to the first embodiment described above.

### Fourth Modification Example of First Embodiment

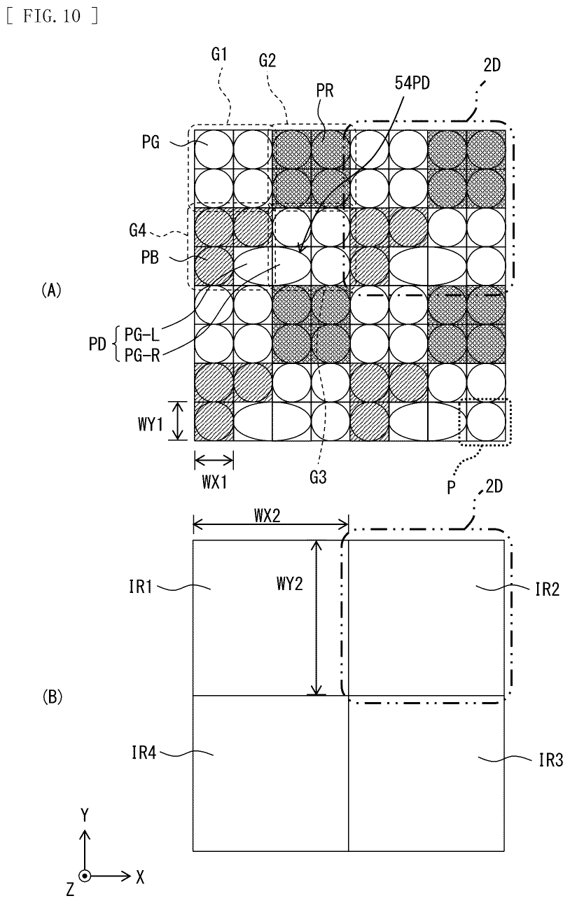

FIG. 10 schematically illustrates a configuration example of a horizontal cross-section of an imaging element 2D according to a fourth modification example (Modification Example 1-4) of the first embodiment. (A) of FIG. 10 and (B) of FIG. 10 respectively correspond to (A) of FIG. 3 and (B) of FIG. 3 that illustrate the imaging element 2 according to the first embodiment described above.

In the imaging element 2D, four pixel groups G1 to G4 arranged in two rows by two columns are allocated to one pixel IR. Four pixels P arranged in two rows by two columns are allocated to each of the pixel group G1 to G3. Three pixels P are allocated only to the pixel group G4. Only green pixels PG are allocated to the pixel group G1. Only red pixels PR are allocated to the pixel group G2. Only green pixels PG are allocated to the pixel group G3. Note that one of the four green pixels PG in the pixel group G3 is replaced with a phase difference detection pixel PD. The phase difference detection pixel PD is provided over a region of the pixel group G3 and a region of the pixel group G4. The phase difference detection pixel PD includes a sub-pixel PD-R positioned in the region of the pixel group G3 and a sub-pixel PD-L positioned in the region of the pixel group G4. The sub-pixel PD-R and the sub-pixel PD-L include an on-chip lens 54PD having one elliptical planar shape. It is desirable that arrangement patterns of the pixels P including the phase difference detection pixel PD in the respective imaging elements 2D be the same. It is to be noted that, in the imaging element 2D, the pixels P other than the phase difference detection pixel PD have no sub-pixel. Except for these points, the configuration of the imaging element 2D is substantially the same as the configuration of the imaging element 2 according to the first embodiment described above.

### Fifth Modification Example of First Embodiment

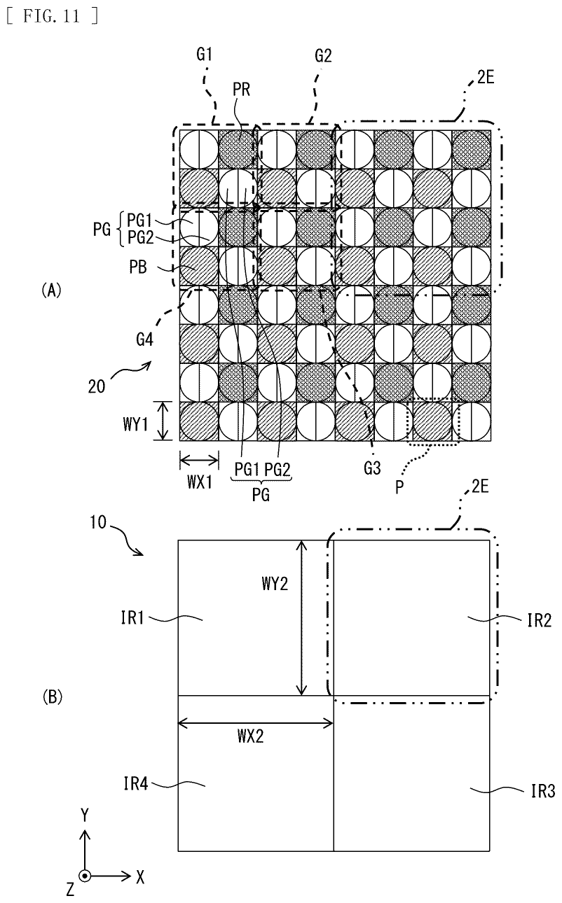

FIG. 11 schematically illustrates a configuration example of a horizontal cross-section of an imaging element 2E according to a fifth modification example (Modification Example 1-5) of the first embodiment. (A) of FIG. 11 and (B) of FIG. 11 respectively correspond to (A) of FIG. 3 and (B) of FIG. 3 that illustrate the imaging element 2 according to the first embodiment described above.

In the imaging element 2E, only the green pixel PG includes sub-pixels PG1 and PG2, and the red pixel PR and the blue pixel PB include no sub-pixel. In other words, only the green pixel PG is usable as a phase difference detection pixel. Except for this point, the configuration of the imaging element 2E is substantially the same as the configuration of the imaging element 2 according to the first embodiment described above.

### Sixth Modification Example of First Embodiment

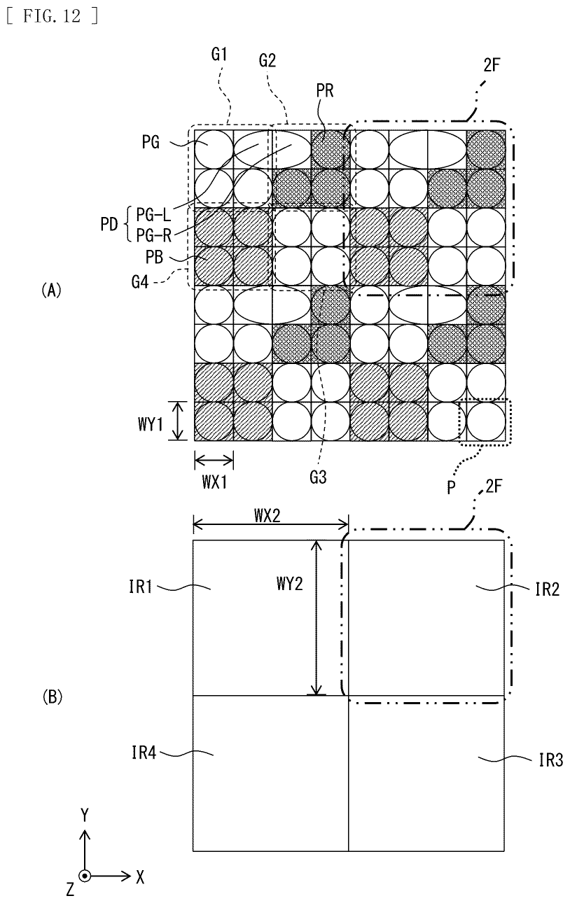

FIG. 12 schematically illustrates a configuration example of a horizontal cross-section of an imaging element 2F according to a sixth modification example (Modification Example 1-6) of the first embodiment. (A) of FIG. 12 and (B) of FIG. 12 respectively correspond to (A) of FIG. 3 and (B) of FIG. 3 that illustrate the imaging element 2 according to the first embodiment described above.

The configuration of the imaging element 2F is substantially the same as the configuration of the imaging element 2D according to the fourth modification example of the first embodiment described above, except that the position where the phase difference detection pixel PD is disposed is different. Specifically, the phase difference detection pixel PD is provided over a region of the pixel group G1 and a region of the pixel group G2.

### Seventh Modification Example of First Embodiment

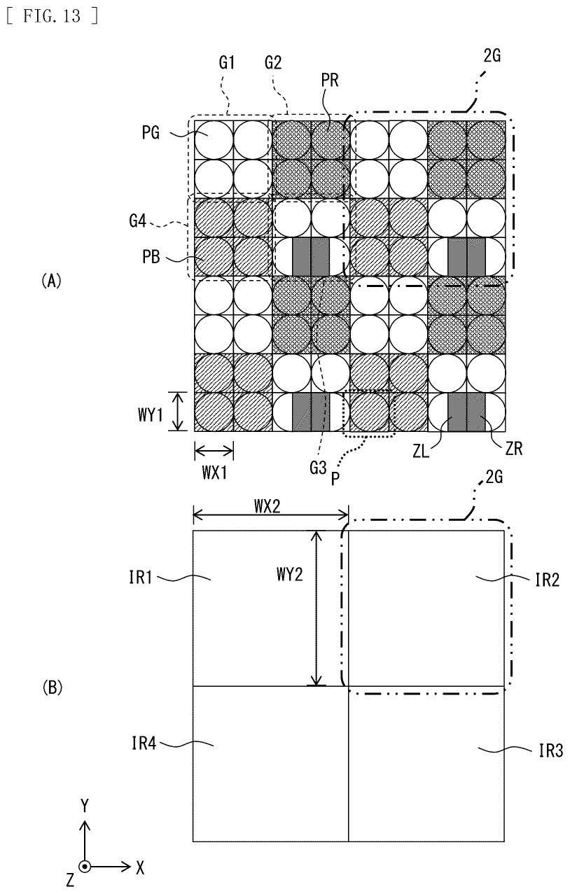

FIG. 13 schematically illustrates a configuration example of a horizontal cross-section of an imaging element 2G according to a seventh modification example (Modification Example 1-7) of the first embodiment. (A) of FIG. 13 and (B) of FIG. 13 respectively correspond to (A) of FIG. 3 and (B) of FIG. 3 that illustrate the imaging element 2 according to the first embodiment described above.

The configuration of the imaging element 2G is substantially the same as the configuration of the imaging element 2C according to the third modification example of the first embodiment described above, except that some of the green pixels PG include a light-shielding film ZL or a light-shielding film ZR and the pixels P include no sub-pixel. Specifically, of the four green pixels PG of the pixel group G3, for example, a first green pixel PG and a second green pixel PG adjacent to each other in the X-axis direction include the light-shielding film ZL or the light-shielding film ZR. The first green pixel PG including the light-shielding film ZL and the second green pixel PG including the light-shielding film ZR are each usable as the phase difference detection pixel.

### 2. Second Embodiment

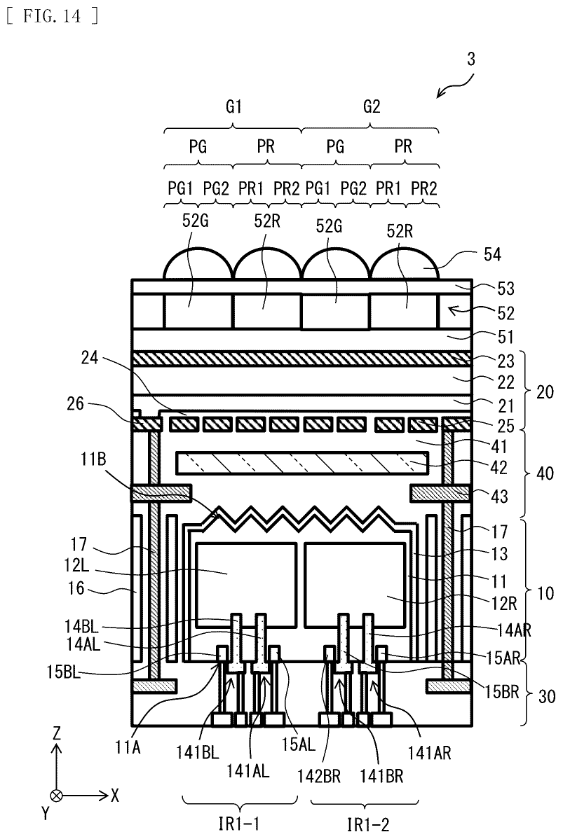

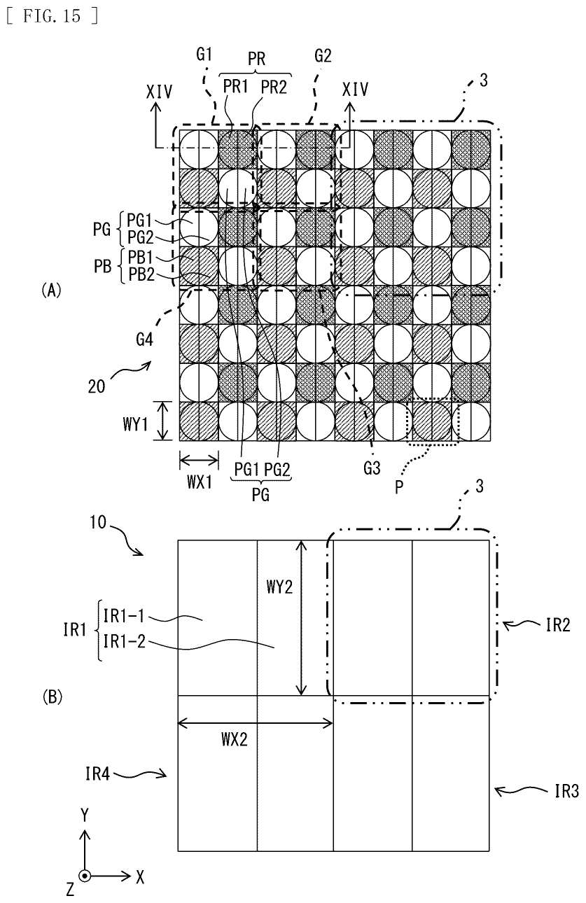

FIG. 14 is a schematic view of a vertical cross-section of an imaging element 3 according to a second embodiment of the present disclosure. FIG. 15 is a schematic horizontal cross-sectional view of an example of a schematic configuration of the imaging element 3. Specifically, (A) of FIG. 15 schematically illustrates an example of a horizontal cross-sectional configuration including the organic photoelectric converter 20, and (B) of FIG. 15 schematically illustrates an example of a horizontal cross-sectional configuration including the photoelectric converter 10. It is to be noted that FIG. 14 illustrates a cross-section taken along a section line XIV-XIV illustrated in FIG. 15 as viewed from the direction of an arrow. In the first embodiment described above, one imaging element 2 includes one pixel IR. In contrast, in the present embodiment, one imaging element 3 includes two or more pixels IR. Except for this point, the imaging element 3 according to the present embodiment has substantially the same configuration as that of the imaging element 2 according to the first embodiment described above.

Specifically, as illustrated in FIGS. 14 and 15, in the photoelectric converter 10, for example, a pixel IR1 includes a sub-pixel IR1-1 and a sub-pixel IR1-2. The sub-pixel IR1-1 (FIG. 15) includes a photoelectric conversion region 12L (FIG. 14), and the sub-pixel IR1-2 (FIG. 15) includes a photoelectric conversion region 12R (FIG. 14). This makes it possible to use the pixel IR1 as a phase difference detection pixel that detects infrared light. The same applies to pixels IR2 to IR4 other than the pixel IR1. It is to be noted that an example illustrated in FIGS. 14 and 15 adopts the organic photoelectric converter 20 having substantially the same configuration as that of the organic photoelectric converter 20 of the imaging element 2 according to the first embodiment described above illustrated in FIG. 2, FIG. 3, and the like; however, the second embodiment is not limited thereto. The imaging element 3 according to the second embodiment of the present disclosure may adopt, for example, the organic photoelectric converter 20 having substantially the same configuration as that of the organic photoelectric converter 20 of the imaging element 2 according to any of Modification Examples 1-1 to 1-7 illustrated in FIGS. 7 to 13.

### First Modification Example of Second Embodiment

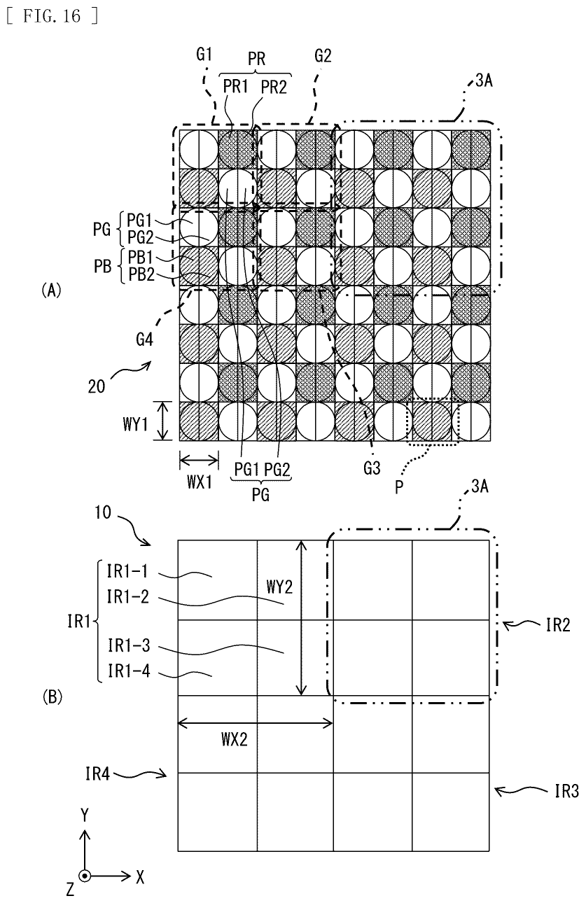

FIG. 16 schematically illustrates a configuration example of a horizontal cross-section of an imaging element 3A according to a first modification example (Modification Example 2-1) of the second embodiment. (A) of FIG. 16 and (B) of FIG. 16 respectively correspond to (A) of FIG. 15 and (B) of FIG. 15 that illustrate the imaging element 3 according to the second embodiment described above.

In the imaging element 3A, each of the pixels IR includes four sub-pixels in the photoelectric converter 10. In the imaging element 3A, for example, the pixel IR1 includes sub-pixels IR1-1 to IR1-4. Except for this pint, the configuration of the imaging element 3A is substantially the same as the configuration of the imaging element 3 according to the second embodiment described above. It is to be noted that an example illustrated in FIG. 16 adopts the organic photoelectric converter 20 having substantially the same configuration as that of the organic photoelectric converter 20 of the imaging element 2 according to the first embodiment described above illustrated in FIG. 2, FIG. 3, and the like; however, the present modification example (Modification Example 2-1) is not limited thereto. The imaging element 3A according to Modification Example 2-1 may adopt, for example, the organic photoelectric converter 20 having substantially the same configuration as that of the organic photoelectric converter 20 of the imaging element 2 according to any of Modification Examples 1-1 to 1-7 illustrated in FIGS. 7 to 13.

### 3. Third Embodiment

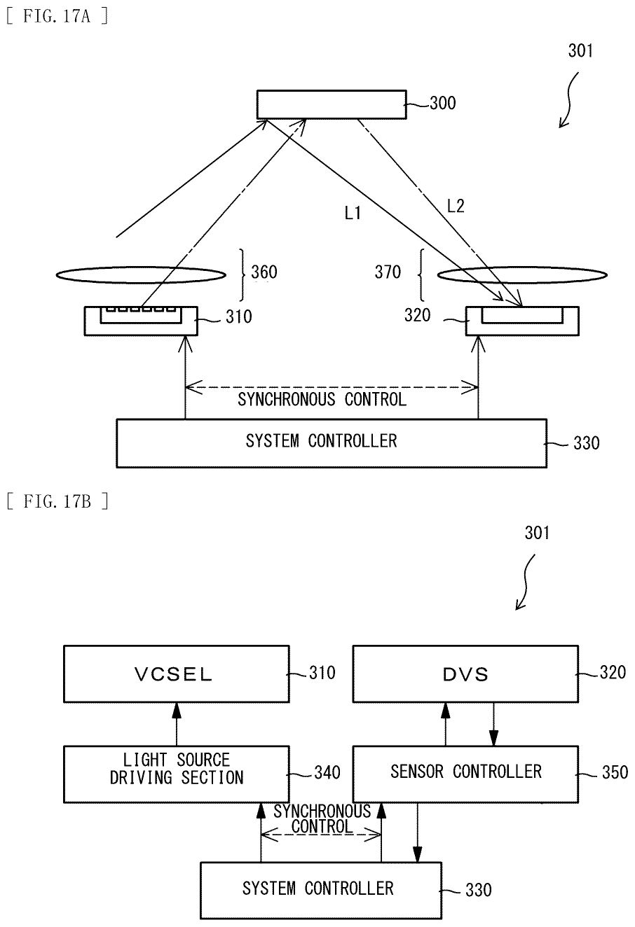

FIG. 17A is a schematic view of an example of an entire configuration of a photodetection system 301 according to a third embodiment of the present disclosure. FIG. 17B is a schematic view of an example of a circuit configuration of the photodetection system 301. The photodetection system 301 includes a light-emitting device 310 as a light source section that emits light L2, and a photodetector 320 as a light-receiving section including a photoelectric conversion element. As the photodetector 320, it is possible to use the solid-state imaging device 1 described above. The photodetection system 301 may further include a system controller 330, a light source driving section 340, a sensor controller 350, a light source-side optical system 360, and a camera-side optical system 370.

The photodetector 320 is able to detect light L1 and the light L2. The light L1 is ambient light from outside reflected by a subject (a measurement object) 300 (FIG. 17A). The light L2 is light emitted from the light-emitting device 310 and then reflected by the subject 300. The light L1 is, for example, visible light, and the light L2 is, for example, infrared light. The light L1 is detectable by an organic photoelectric converter in the photodetector 320, and the light L2 is detectable by a photoelectric converter in the photodetector 320. It is possible to obtain image information of the subject 300 from the light L1 and obtain distance information between the subject 300 and the photodetection system 301 from the light L2. It is possible to mount the photodetection system 301 on, for example, an electronic apparatus such as a smartphone and a mobile body such as a car. It is possible to configure the light-emitting device 310 with, for example, a semiconductor laser, a surface-emitting semiconductor laser, or a vertical cavity surface emitting laser (VCSEL). As a method of detecting the light L2 emitted from the light-emitting device 310 by the photodetector 320, for example, it is possible to adopt an iTOF method; however, the method is not limited thereto. In the iTOF method, the photoelectric converter is able to measure a distance to the subject 300 by time of flight (Time-of-Flight; TOF), for example. As a method of detecting the light L2 emitted from the light-emitting device 310 by the photodetector 320, it is possible to adopt, for example, a structured light method or a stereovision method. For example, in the structured light method, light having a predetermined pattern is projected on the subject 300, and distortion of the pattern is analyzed, thereby making it possible to measure the distance between the photodetection system 301 and the subject 300. In addition, in the stereovision method, for example, two or more cameras are used to obtain two or more images of the subject 300 viewed from two or more different viewpoints, thereby making it possible to measure the distance between the photodetection system 301 and the subject. It is to be noted that it is possible to synchronously control the light-emitting device 310 and the photodetector 320 by the system controller 330.

### 4. Application Example to Electronic Apparatus

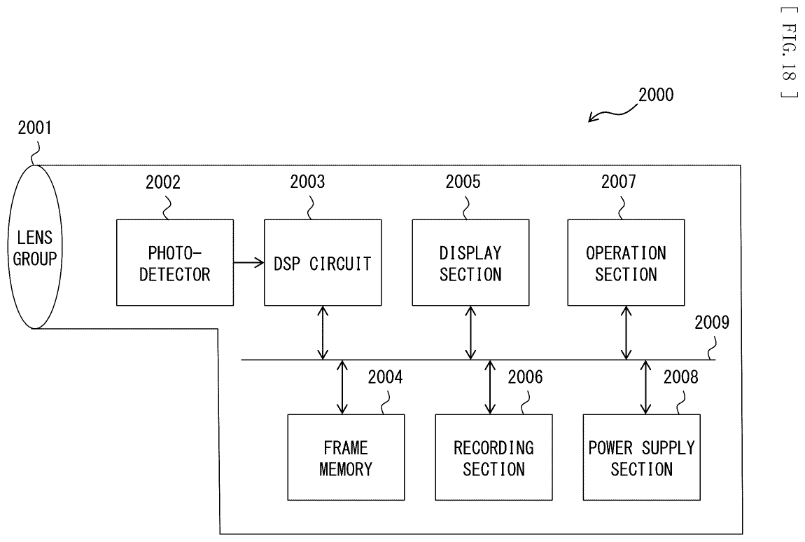

FIG. 18 is a block diagram illustrating a configuration example of an electronic apparatus 2000 to which the present technology is applied. The electronic apparatus 2000 has a function as a camera, for example.

The electronic apparatus 2000 includes an optical section 2001 including a lens group and the like, a photodetector 2002 to which the solid-state imaging device 1 or the like described above (hereinafter referred to as the solid-state imaging device 1 or the like) is applied, and a DSP (Digital Signal Processor) circuit 2003 that is a camera signal processing circuit. In addition, the electronic apparatus 2000 further includes a frame memory 2004, a display section 2005, a recording section 2006, an operation section 2007, and a power supply section 2008. The DSP circuit 2003, the frame memory 2004, the display section 2005, the recording section 2006, the operation section 2007, and the power supply section 2008 are coupled to one another through a bus line 2009.

The optical section 2001 captures incident light (image light) from a subject and forms an image of the incident light on an imaging plane of the photodetector 2002. The photodetector 2002 converts the light amount of the incident light of which the image is formed on the imaging plane by the optical section 2001 into an electric signal on a pixel-by-pixel basis, and outputs the electric signal as a pixel signal.

The display section 2005 includes, for example, a panel type display device such as a liquid crystal panel and an organic EL panel, and displays a moving image or a still image captured by the photodetector 2002. The recording section 2006 records the moving image or the still image captured by the photodetector 2002 on a recording medium such as a hard disk or a semiconductor memory.

The operation section 2007 is operated by a user to issue operation instructions for various functions of the electronic apparatus 2000. The power supply section 2008 supplies the DSP circuit 2003, the frame memory 2004, the display section 2005, the recording section 2006, and the operation section 2007 with various types of power as power for operating these supply targets as appropriate.

As described above, use of the solid-state imaging device 1 or the like described above as the photodetector 2002 makes it possible to expect obtainment of a favorable image.

### 5. Practical Application Example to In-Vivo Information Acquisition System

The technology (present technology) according to the present disclosure is applicable to various products. For example, the technology according to the present disclosure may be applied to an endoscopic surgery system.

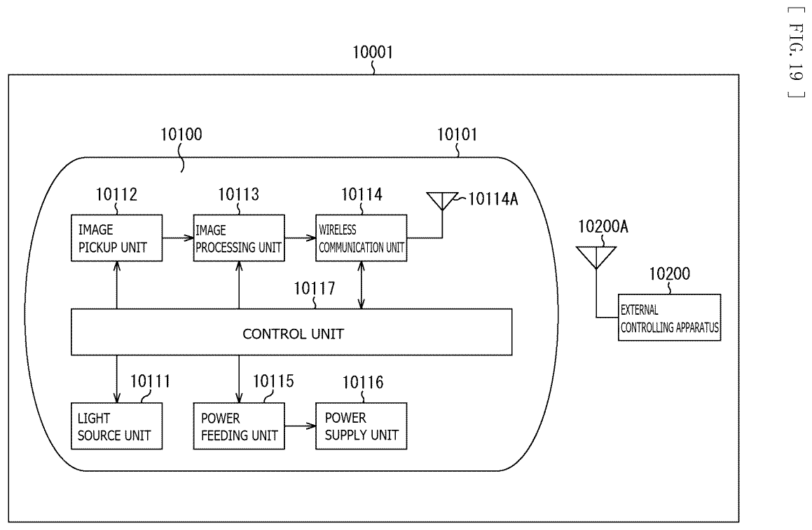

FIG. 19 is a block diagram depicting an example of a schematic configuration of an in-vivo information acquisition system of a patient using a capsule type endoscope, to which the technology according to an embodiment of the present disclosure (present technology) can be applied.

The in-vivo information acquisition system 10001 includes a capsule type endoscope 10100 and an external controlling apparatus 10200.

The capsule type endoscope 10100 is swallowed by a patient at the time of inspection. The capsule type endoscope 10100 has an image pickup function and a wireless communication function and successively picks up an image of the inside of an organ such as the stomach or an intestine (hereinafter referred to as in-vivo image) at predetermined intervals while it moves inside of the organ by peristaltic motion for a period of time until it is naturally discharged from the patient. Then, the capsule type endoscope 10100 successively transmits information of the in-vivo image to the external controlling apparatus 10200 outside the body by wireless transmission.

The external controlling apparatus 10200 integrally controls operation of the in-vivo information acquisition system 10001. Further, the external controlling apparatus 10200 receives information of an in-vivo image transmitted thereto from the capsule type endoscope 10100 and generates image data for displaying the in-vivo image on a display apparatus (not depicted) on the basis of the received information of the in-vivo image.

In the in-vivo information acquisition system 10001, an in-vivo image imaged a state of the inside of the body of a patient can be acquired at any time in this manner for a period of time until the capsule type endoscope 10100 is discharged after it is swallowed.

A configuration and functions of the capsule type endoscope 10100 and the external controlling apparatus 10200 are described in more detail below.

The capsule type endoscope 10100 includes a housing 10101 of the capsule type, in which a light source unit 10111, an image pickup unit 10112, an image processing unit 10113, a wireless communication unit 10114, a power feeding unit 10115, a power supply unit 10116 and a control unit 10117 are accommodated.

The light source unit 10111 includes a light source such as, for example, a light emitting diode (LED) and irradiates light on an image pickup field-of-view of the image pickup unit 10112.

The image pickup unit 10112 includes an image pickup element and an optical system including a plurality of lenses provided at a preceding stage to the image pickup element. Reflected light (hereinafter referred to as observation light) of light irradiated on a body tissue which is an observation target is condensed by the optical system and introduced into the image pickup element. In the image pickup unit 10112, the incident observation light is photoelectrically converted by the image pickup element, by which an image signal corresponding to the observation light is generated. The image signal generated by the image pickup unit 10112 is provided to the image processing unit 10113.

The image processing unit 10113 includes a processor such as a central processing unit (CPU) or a graphics processing unit (GPU) and performs various signal processes for an image signal generated by the image pickup unit 10112. The image processing unit 10113 provides the image signal for which the signal processes have been performed thereby as RAW data to the wireless communication unit 10114.

The wireless communication unit 10114 performs a predetermined process such as a modulation process for the image signal for which the signal processes have been performed by the image processing unit 10113 and transmits the resulting image signal to the external controlling apparatus 10200 through an antenna 10114A. Further, the wireless communication unit 10114 receives a control signal relating to driving control of the capsule type endoscope 10100 from the external controlling apparatus 10200 through the antenna 10114A. The wireless communication unit 10114 provides the control signal received from the external controlling apparatus 10200 to the control unit 10117.

The power feeding unit 10115 includes an antenna coil for power reception, a power regeneration circuit for regenerating electric power from current generated in the antenna coil, a voltage booster circuit and so forth. The power feeding unit 10115 generates electric power using the principle of non-contact charging.

The power supply unit 10116 includes a secondary battery and stores electric power generated by the power feeding unit 10115. In FIG. 19, in order to avoid complicated illustration, an arrow mark indicative of a supply destination of electric power from the power supply unit 10116 and so forth are omitted. However, electric power stored in the power supply unit 10116 is supplied to and can be used to drive the light source unit 10111, the image pickup unit 10112, the image processing unit 10113, the wireless communication unit 10114 and the control unit 10117.

The control unit 10117 includes a processor such as a CPU and suitably controls driving of the light source unit 10111, the image pickup unit 10112, the image processing unit 10113, the wireless communication unit 10114 and the power feeding unit 10115 in accordance with a control signal transmitted thereto from the external controlling apparatus 10200.

The external controlling apparatus 10200 includes a processor such as a CPU or a GPU, a microcomputer, a control board or the like in which a processor and a storage element such as a memory are mixedly incorporated. The external controlling apparatus 10200 transmits a control signal to the control unit 10117 of the capsule type endoscope 10100 through an antenna 10200A to control operation of the capsule type endoscope 10100. In the capsule type endoscope 10100, an irradiation condition of light upon an observation target of the light source unit 10111 can be changed, for example, in accordance with a control signal from the external controlling apparatus 10200. Further, an image pickup condition (for example, a frame rate, an exposure value or the like of the image pickup unit 10112) can be changed in accordance with a control signal from the external controlling apparatus 10200. Further, the substance of processing by the image processing unit 10113 or a condition for transmitting an image signal from the wireless communication unit 10114 (for example, a transmission interval, a transmission image number or the like) may be changed in accordance with a control signal from the external controlling apparatus 10200.

Further, the external controlling apparatus 10200 performs various image processes for an image signal transmitted thereto from the capsule type endoscope 10100 to generate image data for displaying a picked up in-vivo image on the display apparatus. As the image processes, various signal processes can be performed such as, for example, a development process (demosaic process), an image quality improving process (bandwidth enhancement process, a super-resolution process, a noise reduction (NR) process and/or image stabilization process) and/or an enlargement process (electronic zooming process). The external controlling apparatus 10200 controls driving of the display apparatus to cause the display apparatus to display a picked up in-vivo image on the basis of generated image data. Alternatively, the external controlling apparatus 10200 may also control a recording apparatus (not depicted) to record generated image data or control a printing apparatus (not depicted) to output generated image data by printing.

One example of the in-vivo information acquisition system to which the technology according to the present disclosure may be applied has been described above. The technology according to the present disclosure is applicable to, for example, the image pickup unit 10112 among the configurations described above. This makes it possible to achieve high image detection accuracy in spite of a small size.

### 6. Practical Application Example to Endoscopic Surgery System

The technology (present technology) according to the present disclosure is applicable to various products. For example, the technology according to the present disclosure may be applied to an endoscopic surgery system.

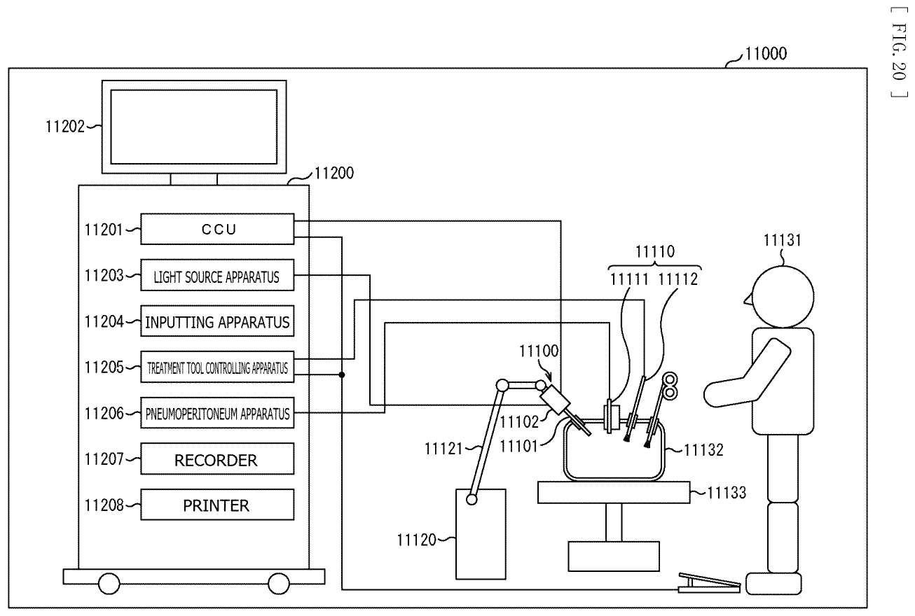

FIG. 20 is a view depicting an example of a schematic configuration of an endoscopic surgery system to which the technology according to an embodiment of the present disclosure (present technology) can be applied.

In FIG. 20, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

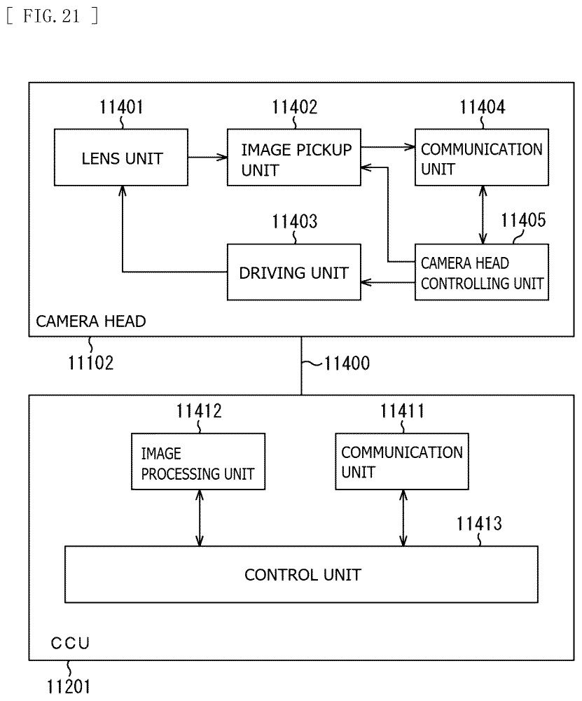

FIG. 21 is a block diagram depicting an example of a functional configuration of the camera head 11102 and the CCU 11201 depicted in FIG. 20.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

One example of the endoscopic surgery system to which the technology according to the present disclosure may be applied has been described above. The technology according to the present disclosure is applicable to, for example, the image pickup unit 11402 of the camera head 11102 among the configurations described above. Applying the technology according to the present disclosure to the image pickup unit 11402 makes it possible to obtain a clearer image of the surgical region, thereby improving viewability of the surgical region for a surgeon.

It is to be noted that the endoscopic surgery system has been described here as an example, but the technology according to the present disclosure may be additionally applied to, for example, a microscopic surgery system and the like.

### 7. Practical Application Example to Mobile Body

The technology (present technology) according to the present disclosure is applicable to various products. For example, the technology according to the present disclosure may be achieved in the form of an apparatus to be mounted to a mobile body of any kind such as an automobile, an electric vehicle, a hybrid electric vehicle, a motorcycle, a bicycle, a personal mobility, an airplane, a drone, a vessel, and a robot.

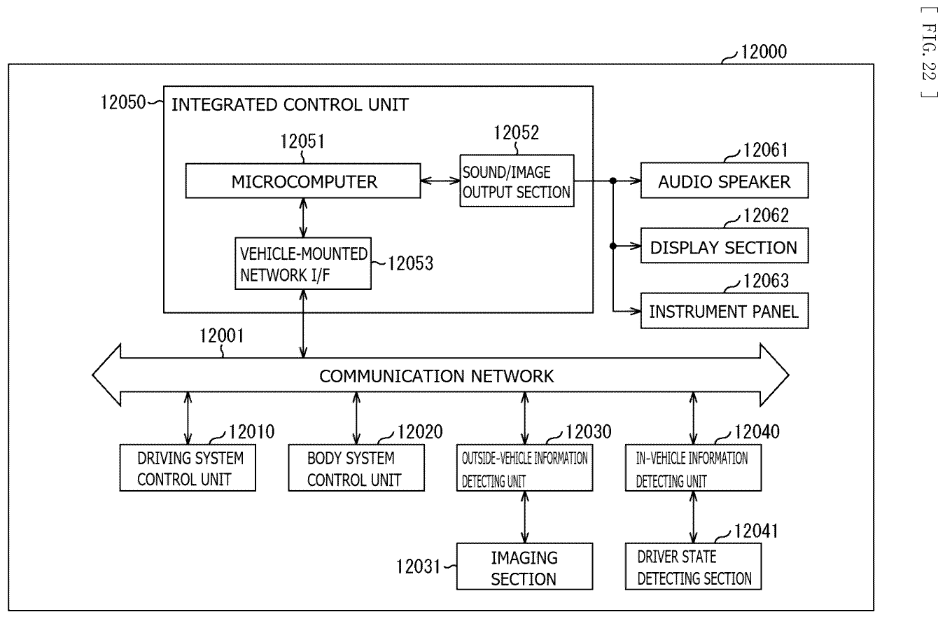

FIG. 22 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 22, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (FF) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 22, an audio speaker 12061, a display section 12062, and an instrument panel 12063 are illustrated as the output device. The display section 12062 may, for example, include at least one of an on-board display and a head-up display.

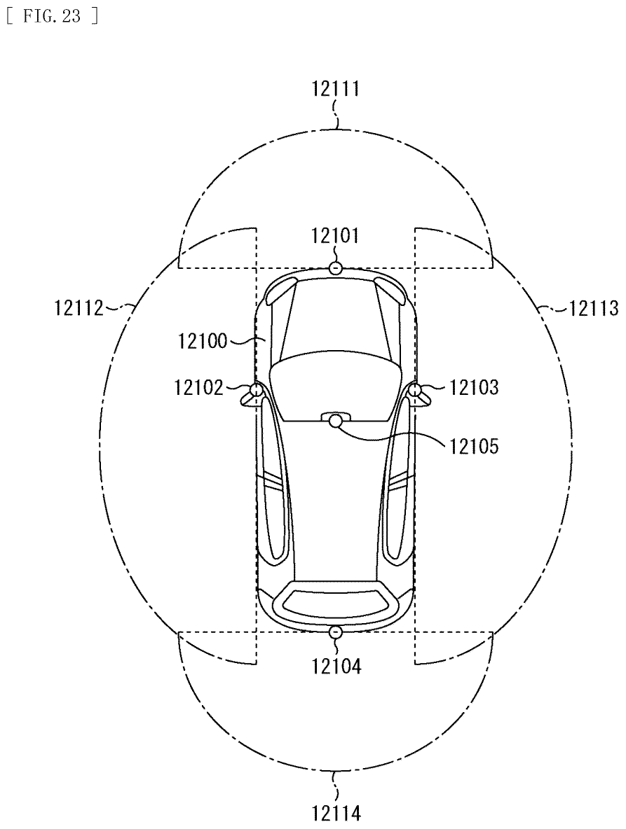

FIG. 23 is a diagram depicting an example of the installation position of the imaging section 12031.

In FIG. 23, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 23 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

One example of the vehicle control system to which the technology according to the present disclosure may be applied has been described above. The technology according to the present disclosure is appliable to the imaging section 12031 among the configurations described above. Applying the technology according to the present disclosure to the imaging section 12031 makes it possible to obtain a shot image that is easier to see. This makes it possible to decrease the fatigue of the driver.

### 8. Other Modification Examples

The present disclosure has been described above with reference to some embodiments and the modification examples, as well as application examples thereof or practical application examples thereof (hereinafter referred to as “embodiments and the like”), but the present disclosure are not limited to the embodiments and the like described above, and may be modified in a variety of ways. For example, the present disclosure is not limited to a back-illuminated image sensor, and is also applicable to a front-illuminated image sensor.

In addition, an imaging device of the present disclosure may have a form of a module in which an imaging section and a signal processor or an optical system are integrally packaged.

Furthermore, in the embodiments and the like described above, the solid-state imaging device in which the light amount of incident light of which an image is formed on an imaging plane through an optical lens system is converted into an electric signal on a pixel-by-pixel basis and the electric signal is outputted as a pixel signal, and the imaging element mounted to the solid-state imaging device have been described as examples; however, a photoelectric conversion element of the present disclosure is not limited to such an imaging element. For example, it is sufficient if the photoelectric conversion element detects and receives light from an subject, and generates electric charges corresponding to the amount of received light by photoelectric conversion and accumulates the electric charges. The signal to be outputted may be a signal of image information or a signal of distance measurement information.

In addition, in the embodiments and the like described above, a case where the photoelectric converter 10 as a second photoelectric converter is an iTOF sensor is described as an example; however, the present disclosure is not limited thereto. That is, the second photoelectric converter is not limited to a photoelectric converter that detects light having a wavelength in the infrared light range, and may be a photoelectric converter that detects light having a wavelength in another wavelength range. In addition, in a case where the photoelectric converter 10 is not an iTOF sensor, only one transfer transistor (TG) may be provided.

Furthermore, in the embodiments and the like described above, the imaging element in which the photoelectric converter 10 including the photoelectric conversion region 12 and the organic photoelectric converter 20 including the organic photoelectric conversion layer 22 are stacked with the intermediate layer 40 interposed therebetween is described as an example of the photoelectric conversion element of the present disclosure; however, the present disclosure is not limited thereto. For example, the photoelectric conversion element of the present disclosure may have a configuration in which two organic photoelectric conversion regions are stacked, or a configuration in which two inorganic photoelectric conversion regions are stacked. In addition, in the embodiments and the like described above, the photoelectric converter 10 detects mainly light having a wavelength in the infrared light range and photoelectrically converts the light, and the organic photoelectric converter 20 detects mainly light having a wavelength in the visible light range and photoelectrically converts the light; however, the photoelectric conversion element of the present disclosure is not limited thereto. In the photoelectric conversion element of the present disclosure, wavelength ranges to which the first photoelectric converter and the second photoelectric converter have sensitivity are freely settable.

In addition, constituent materials of respective components of the photoelectric conversion element of the present disclosure are not limited to the materials described in the embodiments and the like described above. For example, in a case where the first photoelectric converter or the second photoelectric converter receives light in the visible light region and photoelectrically convert the light, the first photoelectric converter or the second photoelectric converter may include a quantum dot.

In a photodetector according to an embodiment of the present disclosure, n times (n is a natural number) a first arrangement period of a plurality of first photoelectric converters in a first direction is substantially equal to a first dimension of one second photoelectric converter in the first direction, and n times (n is a natural number) a second arrangement period of the plurality of first photoelectric converters in a second direction is substantially equal to a second dimension of the one second photoelectric converter in the second direction. This makes it possible to reduce variations in photoelectric conversion characteristics among a plurality of photoelectric conversion elements.

It is to be noted that the effects described herein are merely illustrative and non-limiting, and other effects may be provided. In addition, the present technology may have the following configurations.

(1)

A photoelectric conversion element including:
a first photoelectric converter including a plurality of first photoelectric conversion portions that is periodically arranged in each of a first direction and a second direction orthogonal to each other and each detects light in a first wavelength range and each photoelectrically convert the light; and
a second photoelectric converter stacked on the plurality of first photoelectric converters in a stacking direction orthogonal to both the first direction and the second direction, and including one second photoelectric conversion portion that detects light in a second wavelength range having passed through the plurality of first photoelectric conversion portions and photoelectrically converts the light, in which
n times (n is a natural number) a first arrangement period of the plurality of first photoelectric conversion portions in the first direction is substantially equal to a first dimension of the one second photoelectric conversion portion in the first direction, and
n times (n is a natural number) a second arrangement period of the plurality of first photoelectric conversion portions in the second direction is substantially equal to a second dimension of the one second photoelectric conversion portion in the second direction.
   (2)

The photoelectric conversion element according to (1), in which the first arrangement period and the second arrangement period are substantially equal to each other, and the first dimension and the second dimension are substantially equal to each other.

(3)

The photoelectric conversion element according to (1) or (2), in which the first wavelength range includes a visible light range, and the second wavelength range includes an infrared light range.

(4)

The photoelectric conversion element according to any one of (1) to (3), in which the plurality of first photoelectric conversion portions include a red light detection portion that detects red light and photoelectrically converts the red light, a green light detection portion that detects green light and photoelectrically converts the green light, and a blue light detection portion that detects blue light and photoelectrically converts the blue light.

(5)

The photoelectric conversion element according to (4), in which the red light detection portion, the green light detection portion, and the blue light detection portion are periodically arranged in each of the first direction and the second direction.

(6)

The photoelectric conversion element according to (4) or (5), in which one or more pixel groups each including the red light detection portion, the green light detection portion, and the blue light detection portion are periodically arranged in a region corresponding to the one second photoelectric converter.

(7)

The photoelectric conversion element according to (6), in which, in the pixel group, the red light detection portion, the green light detection portion, and the blue light detection portion are arranged in a Bayer pattern.

(8)

The photoelectric conversion element according to any one of (1) to (7), in which a phase difference detection pixel is included in the plurality of first photoelectric conversion portions.

(9)

The photoelectric conversion element according to (8), in which one of the phase difference detection pixels is configured with two or four first photoelectric conversion portions of the plurality of first photoelectric conversion portions.

(10)

A photodetector provided with a first photoelectric conversion element and a second photoelectric conversion element adjacent to each other along a plane including a first direction and a second direction orthogonal to each other, the first photoelectric conversion element and the second photoelectric conversion element each including:
a first photoelectric converter including a plurality of first photoelectric conversion portions that is periodically arranged in the first direction and periodically arranged in the second direction, and each detects light in a first wavelength range and each photoelectrically convert the light; and
a second photoelectric converter stacked on the first photoelectric converter in a stacking direction orthogonal to both the first direction and the second direction, and including one second photoelectric conversion portion that detects light in a second wavelength range having passed through the plurality of first photoelectric conversion portions and photoelectrically converts the light, in which
in the first photoelectric conversion element and the second photoelectric conversion element,
n times (n is a natural number) a first arrangement period of the plurality of first photoelectric conversion portions in the first direction is substantially equal to a first dimension of the one second photoelectric conversion portion in the first direction, and
n times (n is a natural number) a second arrangement period of the plurality of first photoelectric conversion portions in the second direction is substantially equal to a second dimension of the one second photoelectric conversion portion in the second direction.
   (11)

The photodetector according to (10), in which a first arrangement pattern of the plurality of first photoelectric conversion portions corresponding to the second photoelectric conversion portion in the first photoelectric conversion element and a first arrangement pattern of the plurality of first photoelectric conversion portions corresponding to the second photoelectric conversion portion in the second photoelectric conversion element are equal to each other.

(12)

A photodetector provided with a first photoelectric conversion element and a second photoelectric conversion element adjacent to each other along a first plane, the first photoelectric conversion element and the second photoelectric conversion element each including:
a first photoelectric converter including a plurality of first photoelectric conversion portions that each detects light in a first wavelength range and photoelectrically converts the light; and
a second photoelectric converter stacked on the first photoelectric conversion portion in a stacking direction orthogonal to the first plane, and including one second photoelectric conversion portion that detects light in a second wavelength range having passed through the plurality of first photoelectric conversion portions and photoelectrically converts the light, in which
a light amount distribution of the light in the second wavelength range detected by the second photoelectric converter in the first photoelectric conversion element and a light amount distribution of the light in the second wavelength range detected by the second photoelectric converter in the second photoelectric conversion element are substantially equal to each other.
   (13)

A photodetection system provided with a light-emitting device that emits infrared light and a photodetector that includes a photoelectric conversion element, the photoelectric conversion element including:
a plurality of first photoelectric converters that is periodically arranged in each of a first direction and a second direction orthogonal to each other, and each detects visible light and each photoelectrically convert the visible light; and
a second photoelectric converter that is stacked on the first photoelectric converter in a stacking direction orthogonal to both the first direction and the second direction, and detects the infrared light having passed through the plurality of first photoelectric converters and photoelectrically converts the infrared light, in which
n times (n is a natural number) a first arrangement period of the plurality of first photoelectric converters in the first direction is substantially equal to a first dimension of the second photoelectric converter in the first direction, and
n times (n is a natural number) a second arrangement period of the plurality of first photoelectric converters in the second direction is substantially equal to a second dimension of the second photoelectric converter in the second direction.
   (14)

An electronic apparatus provided with an optical section, a signal processor, and a photoelectric conversion element, the photoelectric conversion element including:
a plurality of first photoelectric converters that is periodically arranged in each of a first direction and a second direction orthogonal to each other, and each detects light in a first wavelength range and each photoelectrically convert the light; and
a second photoelectric converter that is stacked on the first photoelectric converter in a stacking direction orthogonal to both the first direction and the second direction, and detects light in a second wavelength range having passed through the plurality of first photoelectric converters and photoelectrically converts the light, in which
n times (n is a natural number) a first arrangement period of the plurality of first photoelectric converters in the first direction is substantially equal to a first dimension of the second photoelectric converter in the first direction, and
n times (n is a natural number) a second arrangement period of the plurality of first photoelectric converters in the second direction is substantially equal to a second dimension of the second photoelectric converter in the second direction.
   (15)

A mobile body provided with a photodetection system including a light-emitting device and a photodetector, the light-emitting device that emits light in a first wavelength range and light in a second wavelength range, the photodetector including a photoelectric conversion element, the photoelectric conversion element including:
a plurality of first photoelectric converters that is periodically arranged in each of a first direction and a second direction orthogonal to each other, and each detects the light in the first wavelength range and each photoelectrically convert the light; and
a second photoelectric converter that is stacked on the first photoelectric converter in a stacking direction orthogonal to both the first direction and the second direction, and detects the light in the second wavelength range having passed through the plurality of first photoelectric converters and photoelectrically converts the light, in which
n times (n is a natural number) a first arrangement period of the plurality of first photoelectric converters in the first direction is substantially equal to a first dimension of the second photoelectric converter in the first direction, and
n times (n is a natural number) a second arrangement period of the plurality of first photoelectric converters in the second direction is substantially equal to a second dimension of the second photoelectric converter in the second direction.

This application claims the priority on the basis of Japanese Patent Application No. 2020-208719 filed on Dec. 16, 2020 with Japan Patent Office, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

1. A photoelectric conversion element comprising:
a first photoelectric converter including a plurality of first photoelectric conversion portions that is periodically arranged in each of a first direction and a second direction orthogonal to each other and each detects light in a first wavelength range and each photoelectrically convert the light; and
a second photoelectric converter stacked on the plurality of first photoelectric converters in a stacking direction orthogonal to both the first direction and the second direction, and including one second photoelectric conversion portion that detects light in a second wavelength range having passed through the plurality of first photoelectric conversion portions and photoelectrically converts the light, wherein
n times (n is a natural number) a first arrangement period of the plurality of first photoelectric conversion portions in the first direction is substantially equal to a first dimension of the one second photoelectric conversion portion in the first direction, and
n times (n is a natural number) a second arrangement period of the plurality of first photoelectric conversion portions in the second direction is substantially equal to a second dimension of the one second photoelectric conversion portion in the second direction.

2. The photoelectric conversion element according to claim 1, wherein the first arrangement period and the second arrangement period are substantially equal to each other, and the first dimension and the second dimension are substantially equal to each other.

3. The photoelectric conversion element according to claim 1, wherein the first wavelength range comprises a visible light range, and the second wavelength range comprises an infrared light range.

4. The photoelectric conversion element according to claim 1, wherein the plurality of first photoelectric conversion portions include a red light detection portion that detects red light and photoelectrically converts the red light, a green light detection portion that detects green light and photoelectrically converts the green light, and a blue light detection portion that detects blue light and photoelectrically converts the blue light.

5. The photoelectric conversion element according to claim 4, wherein the red light detection portion, the green light detection portion, and the blue light detection portion are periodically arranged in each of the first direction and the second direction.

6. The photoelectric conversion element according to claim 4, wherein one or more pixel groups each including the red light detection portion, the green light detection portion, and the blue light detection portion are periodically arranged in a region corresponding to the one second photoelectric converter.

7. The photoelectric conversion element according to claim 6, wherein, in the pixel group, the red light detection portion, the green light detection portion, and the blue light detection portion are arranged in a Bayer pattern.

8. The photoelectric conversion element according to claim 1, wherein a phase difference detection pixel is included in the plurality of first photoelectric conversion portions.

9. The photoelectric conversion element according to claim 8, wherein one of the phase difference detection pixels is configured with two or four first photoelectric conversion portions of the plurality of first photoelectric conversion portions.

10. A photodetector provided with a first photoelectric conversion element and a second photoelectric conversion element adjacent to each other along a plane including a first direction and a second direction orthogonal to each other, the first photoelectric conversion element and the second photoelectric conversion element each comprising:
a first photoelectric converter including a plurality of first photoelectric conversion portions that is periodically arranged in the first direction and periodically arranged in the second direction, and each detects light in a first wavelength range and each photoelectrically convert the light; and
a second photoelectric converter stacked on the first photoelectric converter in a stacking direction orthogonal to both the first direction and the second direction, and including one second photoelectric conversion portion that detects light in a second wavelength range having passed through the plurality of first photoelectric conversion portions and photoelectrically converts the light, wherein
in the first photoelectric conversion element and the second photoelectric conversion element,
n times (n is a natural number) a first arrangement period of the plurality of first photoelectric conversion portions in the first direction is substantially equal to a first dimension of the one second photoelectric conversion portion in the first direction, and
n times (n is a natural number) a second arrangement period of the plurality of first photoelectric conversion portions in the second direction is substantially equal to a second dimension of the one second photoelectric conversion portion in the second direction.

11. The photodetector according to claim 10, wherein a first arrangement pattern of the plurality of first photoelectric conversion portions corresponding to the second photoelectric conversion portion in the first photoelectric conversion element and a first arrangement pattern of the plurality of first photoelectric conversion portions corresponding to the second photoelectric conversion portion in the second photoelectric conversion element are equal to each other.

12. A photodetector provided with a first photoelectric conversion element and a second photoelectric conversion element adjacent to each other along a first plane, the first photoelectric conversion element and the second photoelectric conversion element each comprising:
a first photoelectric converter including a plurality of first photoelectric conversion portions that each detects light in a first wavelength range and photoelectrically converts the light; and
a second photoelectric converter stacked on the first photoelectric conversion portion in a stacking direction orthogonal to the first plane, and including one second photoelectric conversion portion that detects light in a second wavelength range having passed through the plurality of first photoelectric conversion portions and photoelectrically converts the light, wherein
a light amount distribution of the light in the second wavelength range detected by the second photoelectric converter in the first photoelectric conversion element and a light amount distribution of the light in the second wavelength range detected by the second photoelectric converter in the second photoelectric conversion element are substantially equal to each other.

13. A photodetection system provided with a light-emitting device that emits infrared light and a photodetector that includes a photoelectric conversion element, the photoelectric conversion element comprising:
a plurality of first photoelectric converters that is periodically arranged in each of a first direction and a second direction orthogonal to each other, and each detects visible light and each photoelectrically convert the visible light; and
a second photoelectric converter that is stacked on the first photoelectric converter in a stacking direction orthogonal to both the first direction and the second direction, and detects the infrared light having passed through the plurality of first photoelectric converters and photoelectrically converts the infrared light, wherein
n times (n is a natural number) a first arrangement period of the plurality of first photoelectric converters in the first direction is substantially equal to a first dimension of the second photoelectric converter in the first direction, and
n times (n is a natural number) a second arrangement period of the plurality of first photoelectric converters in the second direction is substantially equal to a second dimension of the second photoelectric converter in the second direction.

14. An electronic apparatus provided with an optical section, a signal processor, and a photoelectric conversion element, the photoelectric conversion element comprising:
a plurality of first photoelectric converters that is periodically arranged in each of a first direction and a second direction orthogonal to each other, and each detects light in a first wavelength range and each photoelectrically convert the light; and
a second photoelectric converter that is stacked on the first photoelectric converter in a stacking direction orthogonal to both the first direction and the second direction, and detects light in a second wavelength range having passed through the plurality of first photoelectric converters and photoelectrically converts the light, wherein
n times (n is a natural number) a first arrangement period of the plurality of first photoelectric converters in the first direction is substantially equal to a first dimension of the second photoelectric converter in the first direction, and
n times (n is a natural number) a second arrangement period of the plurality of first photoelectric converters in the second direction is substantially equal to a second dimension of the second photoelectric converter in the second direction.

15. A mobile body provided with a photodetection system including a light-emitting device and a photodetector, the light-emitting device that emits light in a first wavelength range and light in a second wavelength range, the photodetector including a photoelectric conversion element, the photoelectric conversion element comprising:
a plurality of first photoelectric converters that is periodically arranged in each of a first direction and a second direction orthogonal to each other, and each detects the light in the first wavelength range and each photoelectrically convert the light; and
a second photoelectric converter that is stacked on the first photoelectric converter in a stacking direction orthogonal to both the first direction and the second direction, and detects the light in the second wavelength range having passed through the plurality of first photoelectric converters and photoelectrically converts the light, wherein
n times (n is a natural number) a first arrangement period of the plurality of first photoelectric converters in the first direction is substantially equal to a first dimension of the second photoelectric converter in the first direction, and
n times (n is a natural number) a second arrangement period of the plurality of first photoelectric converters in the second direction is substantially equal to a second dimension of the second photoelectric converter in the second direction.
